(19) United States
(12) Patent Application Publication
(10) Pub. No.: US 2021/0351863 A1
(43) Pub. Date: Nov. 11, 2021

(54) JOINT SOURCE CHANNEL CODING BASED ON CHANNEL CAPACITY USING NEURAL NETWORKS

(71) Applicant: Imperial College of Science, Technology and Medicine, London, Greater London (GB)

(72) Inventor: Deniz Gunduz, Reading (GB)

(73) Assignee: Imperial College of Science, Technology and Medicine, London, Greater London (GB)

(21) Appl. No.: 17/268,430

(22) PCT Filed: Aug. 14, 2019
(86) PCT No.: PCT/GB2019/052284

§ 371 Date: Feb. 12, 2021

(30) Foreign Application Priority Data
Aug. 15, 2018 (GB) 1813354.6

(51) Int. Cl. H04L 1/00; H03M 13/00; G06N 3/08; G06N 3/04

(52) U.S. Cl. CPC H04L 1/0009; G06N 3/0454; G06N 3/088; H03M 13/6312

(57) ABSTRACT

A communication system for conveying information from an information source across a communications channel using a joint source channel coding autoencoder, comprising: an encoder neural network of the joint source channel coding autoencoder, the encoder neural network having: an input layer having input nodes corresponding to a sequence of source symbols S^{m}={S₁, S₂, . . . , Sₘ}, the Sᵢ, taking values in an alphabet S, received at the input layer from the information source as samples thereof, and a channel input layer coupled to the input layer through one or more neural network layers, the channel input layer having nodes usable to provide values for the Xᵢ, of a channel input vector Xⁿ={X₁, X₂, . . . , Xₙ}, the Xᵢ, taking values from the available input signal alphabet X of the communications channel, the channel input vector Xⁿ comprising a plurality of signal values X^{p} usable to reconstruct an information source, wherein the number p of the plurality of signal values X^{p} is smaller than the total number n of signal values of the channel input vector Xⁿ, and wherein at least one of the remaining signal values of the channel input vector Xⁿ is usable to increase the quality of the reconstructed information source, and wherein the encoder neural network is configured through training to be usable to map sequences of source symbols S^{m} received from the information source directly to a representation as a channel input vector Xⁿ, usable to drive a transmitter to transmit a corresponding signal over the communications channel; a first decoder neural network and a second decoder neural network of the joint source channel coding autoencoder, each decoder neural network having: a channel output layer having nodes corresponding to a channel output vector Y received from a receiver receiving a signal corresponding to at least the plurality of signal values X^{p} of the channel input vector Xⁿ transmitted by the transmitter and transformed by the communications channel, and an output layer coupled to the channel output layer through one or more neural network layers, having nodes matching those of the input layer of the encoder neural network, wherein the first decoder neural network is configured through training to map the representation of the source symbols as the channel output vector Y transformed by the communications channel to a reconstruction of the source symbols Ŝ^{m} output from the output layer of the joint source channel coding autoencoder, the reconstruction of the source symbols Ŝ^{m} being usable to reconstitute the information source; and wherein the number of signal values of the channel output vector Y received by the first decoder network is more than the number of signal values of the channel output vector Y received by the second decoder neural network.

This present application provides disclosures relating to communication systems for conveying information from an information source across a communications channel using joint source channel coding, in particular by the use of an encoder neural network and decoder neural network providing a joint source channel coding autoencoder.

### BACKGROUND

An aim of a data communication system is to efficiently and reliably send data from an information source over a communication channel from a transmitter at as high a rate as possible with as few errors as achievable in view of the channel noise, to enable a faithful representation of the original information source to be recovered at a transmitter.

Most digital communication systems today include a source encoder and separate channel encoder at a transmitter and a source decoder and separate channel decoder at a receiver.

Information sources to be transmitted over the channel generally store or generate ‘raw’ or ‘uncompressed’ data directly or indirectly representative of characteristics of the information source, to allow faithful reproduction of the information source by a given combination of data processing hardware appropriately configured, for example by software or firmware. The information source may be representative of images, documents, audio or video recordings, sensor data, and so on. The information source is any information source suitable for arranging as a sequence of source symbols or fundamental data elements (for example, bits), such as static files or databases or arranged as a sequence over time, as in a stream of data from a sensor or a video camera.

In digital communications systems, to transmit data from the information source over a communications channel, the source symbols are first digitally compressed into bits by the source encoder. The goal in source coding is to encode the sequence of source symbols into a coded representation of data elements to reduce the redundancy in the original sequence of source symbols. In lossless compression one has to remove redundancy such that the original information source can still be reconstructed as the original version from the coded representation, while lossy compression allows a certain amount of degradation in the reconstructed version under some specified distortion measure, for example squared error. JPEG for images, or H264/MPEG for videos are examples of lossy source compression standards widely used in practice. Compressing the information source using a source encoder before transmission means that fewer resources are required for that transmission.

Once the data from the information source has been encoded to compress it down in size, to transfer this representation over a communication channel, the output of the source encoder is then provided to a channel encoder. The goal of the channel encoder is to encode the compressed data representation in a structured way using a suitable Error Correction Code (ECC) by adding redundancy such that even if some of these bits are distorted or lost due to noise over the channel, the receiver can still recover the original sequence of bits reliably. The amount of redundancy that is added depends on the statistical properties of the underlying communication channel and a target Bit Error Rate (BER). Generally, such channel coding schemes using Forward Error Correction (FEC) provide for a faithful recovery of the transmitted data elements (such as a compressed data source) where the noise on the channel leads to a quality of signal reception below a maximum BER. However, due to the cliff effect, as channel noise increases, BER will increase drastically and, when the channel noise is too high and a maximum BER is breached, the signal transmission will drop out completely, meaning the transmitted data cannot be recovered. There are many different channel coding techniques in practice that provide various complexity and performance trade-offs. Turbo codes and Low-density parity-check (LDPC) codes are examples of ECCs that are commonly used in modern communication systems such as WMAX and fourth generation Long-Term Evolution (LTE) mobile communications.

The coded bits at the output of the channel encoder are transmitted over the channel using a modulator. The modulator converts the bits into signals that can be transmitted over the communication medium. For example, in wireless systems using Quadrature Modulation of two out of phase amplitude modulated carrier signals, the transmitted waveform is specified by its In-Phase (I) and Quadrature (Q) components, and a modulator typically has a discrete set of pre-specified I and Q values, called a constellation, and each group of coded information bits are mapped to a single point in this constellation. Example modulation schemes include phase shift keying (PSK) and quadrature amplitude modulation (QAM).

The receiver receives and demodulates (for example, by coherent demodulation) a sequence of noisy symbols, where the noise has been added by the communications channel. These noisy demodulated symbols are then mapped to sequences of data elements by a channel decoder. The decoded data elements are then passed to the source decoder, which decodes these data elements to try to reconstruct a representation of the originally input source symbols to reconstruct the information source.

Naturally, the source encoder and decoder are designed jointly, as are the channel encoder and decoder, but as can be seen the source encoder/decoder and channel encoder/decoder are designed and operate separately to perform very different functions.

The main advantage of separate source and channel coding is the modularity it provides. This means that the same channel encoder and decoder can be used in conjunction with any source encoder and decoder. That is, as long as the source encoder outputs data elements that can be encoded by the channel encoder, it does not matter if these bits come from an image compressor or a video encoder. Thus a channel encoder can encode data elements for transmission over a channel irrespective of the data elements or the information source from which they have been derived.

Similarly, the source encoder and decoder can be operated in conjunction with any channel encoder and decoder to transmit the encoded source symbols over a communications channel. Thus a source encoder can encode data elements for subsequent coding by the channel encoder independently of which channel encoder is used.

It is in the above context that the present disclosure has been devised.

### BRIEF SUMMARY OF THE DISCLOSURE

The present inventors have realised that, despite the significant advantage of modularity that separate source and channel coding provides, it has disadvantages which may render this approach to have a deleterious effect on communication systems, particularly those trying to send relatively large amounts of data over noisy channels under latency or energy constraints. In particular, the reduction of data redundancy by the source encoder followed by the independent adding of redundancy by the channel encoder, although optimal theoretically in the limit of infinite length source blocks and infinite length channel codes, may introduce inefficiencies into the data transmission in practice when the source and channel blocks are relatively short. Further, separate source and channel coding is highly complex, and is therefore slow and consumes large amounts of energy due to the computational resources required to execute the source and channel coding, which may add a significant drain on the energy resources of battery-powered devices.

As the volume of data required to be transmitted over communications channels increases, to accommodate this, the resources allocated to the communications system must be increased to provide increased channel capacity which places a burden on the transmitter and receiver. Alternatively, or in addition, the information source must be compressed in an even more lossy fashion, which impacts on the quality of the reconstruction of the information source at the receiver.

It is in this context that the presently disclosed joint source channel coding autoencoder for use in a communication system for conveying information from an information source across a communications channel has been devised.

In consideration of the context of the above background, the present inventors have realised that using a joint source channel coding autoencoder to convey information from an information source across a communications channel would provide an advantageous means of providing a simple and flexible communication system addressing the limitations of current communication systems.

Moreover, the present inventors have realised that using multiple joint source channel coding autoencoders to convey information from different information sources or different types of information source across a communications channel would provide an advantageous means of providing a flexible and efficient communication system.

Thus, viewed from one aspect, the present disclosure provides a transmitter device for conveying information from an information source across a communications channel using a joint source channel coding autoencoder, comprising: a plurality of encoder neural networks, each encoder neural network of a joint source channel coding autoencoder, and each encoder neural network trained to receive a different information source or a different type of information source. Each encoder neural network may comprise: an input layer having input nodes corresponding to a sequence of source symbols S^{m}={S₁, S₂, . . . , Sₘ}, the Sᵢ taking values in a finite alphabet S, received at the input layer from an information source as samples thereof, and a channel input layer coupled to the input layer through one or more neural network layers, the channel input layer having nodes usable to provide values for the Xᵢ of a channel input vector Xⁿ={X₁, X₂, . . . , Xₙ}, the Xᵢ taking values from the available input signal alphabet X of the communications channel, wherein the encoder neural network is configured through training to be usable to map sequences of source symbols S^{m} received from the information source directly to a representation as a channel input vector Xⁿ, usable to drive a transmitter to transmit a corresponding signal over a communications channel; and a transmitter to transmit the channel input vector Xⁿ over the communications channel.

In accordance with the presently disclosed communication system, an autoencoder is provided that is trained to perform joint source and channel coding (referred to as “joint source channel coding”) in which the information source, or sequences of raw, unencoded symbols generated thereby, are mapped by an encoder neural network directly to signal values of a channel input vector to drive a transmitter to transmit the encoded data over the communications channel. That is, for example, the encoder neural network may map a sequence of input symbols representative of an uncompressed frame of a video stream directly to values of a channel input vector (for example, the I and Q values for a Quadrature Modulation transmission scheme). On receipt at the receiver of a transmitted channel input vector having noise added by the communications channel, this is directly decoded using a decoder neural network trained together with the encoder neural network, to recover a representation of the original source symbols.

Thus in accordance with the present disclosure, the channel input symbols are generated directly from the source signal (no separate source and channel encoders) using a neural network. This is a joint source channel coding scheme, which is a technique used in analogue communication systems, where the carrier signal is modulated directly with the information source, e.g., an audio signal, without converting it to bits. However, the joint source channel coding scheme of the present disclosure that uses an autoencoder is not analogue communication, since the underlying information source (possibly continuous) is sampled digitally, and the goal is to transmit these sample values over the channel. Therefore, the joint source channel coding autoencoder of the present disclosure gets rid of the separate source encoder (which converts the samples into bits) and the separate channel encoder (which encodes these bits into channel codewords) and combines the two into one joint encoder that maps the information source samples directly into channel inputs.

Neural networks learn through training to produce the optimum output. The encoder neural network and decoder neural network of the joint source channel coding encoder are trained jointly to generate a high fidelity reconstruction of the input. They can be trained for different input sources and different channel noise. This reduces the complexity of the communication system whilst ensuring the system is flexible and can be utilised with a variety of information sources and channels.

Joint source and channel coding in digital systems lacks the modularity to encode different information sources to different communications channels that is afforded by separate source and channel coding schemes. Thus in digital systems where data sampled from different information sources needs to be transmitted, joint source channel coding has been avoided as different joint source channel codes would have been needed to have been written for each different information source and modulation scheme, with the loss of modularity making this approach impractical. However, in accordance with the present disclosure, where an autoencoder is used for joint source channel coding, an encoder neural network and decoder neural network can be automatically trained to optimally map a given information source (or type of information source) to a given communications channel (taking account of the noise), without the user or the transmitter operating the neural network having to understand how the information source is being encoded. Thus the advantages of data transmission efficiency and low resource burdens of using optimised joint source channel coding schemes can be realised by training of an appropriately structured neural network using a training process, without having to manually define the coding scheme. Thus the perceived problems of loss of modularity do not present barriers to realistic implementation of joint source channel coding, when the autoencoders of the present disclosure are used.

The neural network can learn the channel behaviour to ensure that the information source can be reconstructed at any channel quality. This enables any input into the decoder neural network to produce a sufficient output, even if the communication channel is unknown. For example, the input may be random or may be a non-trained image and a meaningful output can still be produced.

The encoder neural network is configured through training to map sequences of source symbols S^{m} received from the information source directly to a representation as a channel input vector Xⁿ, usable to drive a transmitter to transmit a corresponding signal over the communications channel. The direct mapping ensures the communications system is streamlined to reduce the time taken to transmit signals and to reduce the complexity of the system.

Further, the transmitter device of the present disclosure comprises a plurality of encoder neural networks, each encoder neural network of a joint source channel coding autoencoder, and each encoder neural network trained to receive a different information source or a different type of information source. Each encoder neural network can be trained for a specific information source and so is highly efficient at encoding the information source for transmission. Thus, the transmitter device is capable of receiving a plurality of different information sources or types of information source and efficiently transmitting each information source. Moreover, each encoder neural network can also be retrained for a different type of information source. Thus, the transmitter device is also flexible and can adapt if the information sources or types of information source being input into the device are changed. The training of the different autoencoders for joint source channel coding of different information sources addresses the inherent lack of modularity in joint source channel coding, and so a transmitter device can be provided with multiple autoencoders for transmission of multiple different information sources by joint source channel coding, each autoencoder being trained to efficiently map a respective information source to the channel for transmission. The or each receiver can be provided with the respective complementary (and jointly trained) decoder part of the autoencoder to allow the coded information source transmitted over the communications channel to be decoded at the or each receiver.

Thus, there is provided a simple and flexible communications system with improved capabilities for the transmission and reception of different information sources or types of information sources.

Each encoder neural network may be of a different joint source channel coding autoencoder.

Each encoder network may receive a different size information source.

Each encoder neural network may have a different number of nodes at the channel input layer.

The information source of one of the plurality of encoder neural networks may be an image and the information source of another of the plurality of encoder neural networks may be a video.

The transmitter may transmit each channel input vector Xⁿ at a different frequency over the communications channel.

The transmitter may transmit each channel input vector Xⁿ simultaneously over the communications channel.

For at least one encoder neural network, the channel input layer of the encoder neural network may have nodes corresponding to the channel input vector Xⁿ and the sequences of source symbols S^{m} may be mapped directly to a representation as the channel input vector Xⁿ.

Each joint source channel coding autoencoder may be a joint source channel coding variational autoencoder, wherein the nodes of the channel input layer of each encoder neural network may correspond to a channel input distribution vector Z^{k}={Z₁, Z₂, . . . , Z_{K}}, the Zᵢ taking values for parameters defining a plurality of distributions, each distribution being sampleable to provide possible values for the X of the channel input vector Xⁿ={X₁, X₂, . . . , Xₙ}, and wherein each encoder neural network may be configured through training to map sequences of source symbols S^{m} received from the information source directly to a representation as a plurality of distributions that provide possible values for the Xᵢ of a channel input vector Xⁿ, the transmitter device may further comprise: a sampler, configured to produce a channel input vector Xⁿ={X₁, X₂, . . . , Xₙ} in use by sampling the respective distribution for each channel input Xᵢ defined by the channel input distribution vector Z^{k}={Z₁, Z₂, . . . , Z_{K}} output by the channel input layer of each encoder neural network.

The transmitter device may be in combination with one or more receiver devices, each receiver device may comprise: at least one decoder neural network which may correspond to one of the plurality of encoder neural networks of the transmitter device. The decoder neural network may have: a channel output layer having nodes corresponding to a channel output vector Yⁿ received from a receiver receiving a signal corresponding to at least the plurality of symbols X^{p} of the channel input vector Xⁿ transmitted by the transmitter and transformed by the communications channel, and an output layer coupled to the channel output layer through one or more neural network layers, having nodes matching those of the input layer of the encoder neural network, wherein the first decoder neural network is configured through training to map the representation of the source symbols as the channel output vector Yⁿ transformed by the communications channel to a reconstruction of the source symbols Ŝ^{m} output from the output layer of the joint source channel coding autoencoder, the reconstruction of the source symbols Ŝ^{m} being usable to reconstitute the information source; and a receiver to receive a signal corresponding to the channel input vector Xⁿ transmitted by the transmitter of the transmitter device over the communications channel.

The transmitter device may be in combination with a receiver device that may comprise: a plurality of decoder neural networks, each decoder neural network may correspond to one of the plurality of encoder neural networks of the transmitter device, each decoder neural network may have: a channel output layer having nodes corresponding to a channel output vector Yⁿ received from a receiver receiving a signal corresponding to at least the plurality of symbols X^{p} of the channel input vector Xⁿ transmitted by the transmitter and transformed by the communications channel, and an output layer coupled to the channel output layer through one or more neural network layers, having nodes matching those of the input layer of the encoder neural network, wherein the first decoder neural network is configured through training to map the representation of the source symbols as the channel output vector Yⁿ transformed by the communications channel to a reconstruction of the source symbols Ŝ^{m} output from the output layer of the joint source channel coding autoencoder, the reconstruction of the source symbols Ŝ^{m} being usable to reconstitute the information source; and a receiver to receive a signal corresponding to the channel input vector Xⁿ transmitted by the transmitter of the transmitter device over the communications channel.

For at least one of the plurality of encoder neural networks, the size n of the channel input vector Xⁿ may be smaller than the size m of the source symbols S^{m} and the information source may be compressed during mapping.

For at least one of the plurality of encoder neural networks, the size n of the channel input vector Xⁿ may be based on the channel capacity.

For at least one of the plurality of encoder neural networks, the size n of the channel input vector Xⁿ may be based on the information source or type of information source.

For at least one of the plurality of encoder neural networks, the size m of the sequence of source symbols S^{m} may be based on the information source or type of information source.

For at least one of the plurality of encoder neural networks, the encoder neural network and corresponding decoder neural network may be trained jointly.

For at least one of the plurality of encoder neural networks, the encoder neural network and decoder neural network may be trained jointly to minimise the difference between the input and output of the joint source channel coding variational autoencoder.

For at least one of the plurality of encoder neural networks, the encoder neural network and decoder neural network may be trained jointly based on the type of communications channel.

For at least one of the plurality of encoder neural networks, the encoder neural network and decoder neural network may be trained jointly based on a model of the communication channel, and the decoder neural network may be trained further based on the real communication channel using one way communication of known training data samples from the transmitter to the receiver.

For at least one of the plurality of encoder neural networks, the encoder neural network and decoder neural network may be trained jointly based on the type of information source, or for a given information source.

For at least one of the plurality of encoder neural networks, the information source may not have been compressed before being input into the joint source channel coding variational autoencoder.

For at least one of the plurality of encoder neural networks, the communications channel may be a noisy communications channel.

Referring back to separate source and channel coding, when the same signal is broadcasted to multiple receivers, separate source and channel coding is designed based on the receiver with the poorest capabilities or the receiver with the worst channel quality. There is no flexibility as to what each receiver receives which will lead to wasted resources for at least one of the receivers. For example, receivers with a higher channel quality may receive a signal to be transmitted over a channel with a low channel quality, and said signal may be of a larger size than the signal needed for transmission over the high quality channel. For example, the signal may be compressed less and have more redundancy added to enable reconstruction at the receiver with the low quality channel. Thus, the signal transmitted across the communication channel may be larger than necessary and consume more bandwidth, making the system inefficient. Alternatively, if the transmission is to a receiver with poor capabilities, for example that can only receive a small number of signal values or is slower at receiving symbols, then the separate source and channel coding will be designed based on this receiver and so the signal may contain less symbols. This means that receivers with good capabilities, such as receivers able to receive more signal values for reconstruction, may receive a signal with a smaller number of signal values and may not be able to fully utilise its capabilities. Receivers with much higher channel qualities or with better capabilities would therefore be limited by a single weak receiver. Thus the reconstruction at these receivers may be of a lower quality due to receiving fewer signal values, making the system inefficient.

In another example, if the transmission is to receivers that do not need to receive a large number of signal values and do not need to reconstruct the information source to a high quality and also receivers that do need to receive a large number of signal values and do need to reconstruct the information source to a high quality, the separate source and channel coding will be based on the receivers that need to receive a large number of symbols. This is detrimental for receivers that do not need to receive a large number of signal values as they will still have to receive all the signal values to reconstruct the information source, wasting time, bandwidth and energy of the receiver. For example, if the receiver only requires a small number of signal values to enable fast reconstruction, the receiver may not be able to reconstruct as fast as it could due to the limitations of another receiver.

In another example, when a signal is transmitted to a receiver, separate source and channel coding is designed based on the channel bandwidth. If there is additional bandwidth available, this is not utilised, even if the receiver is capable of receiving additional information.

It is in this context that the presently disclosed joint source channel coding autoencoder for use in a communication system for conveying information from an information source across a communications channel has been devised. In consideration of the context of the above background, the present inventors have realised that using a joint source channel coding autoencoder to convey information from an information source across a communications channel would provide an advantageous means of providing a simple and flexible communication system addressing the limitations of current communication systems. Moreover, the present inventors have realised that transmitting a channel input vector comprising signal values usable to reconstruct an information source and additional signal values for improvement of the reconstruction would provide an advantageous means of providing a flexible and efficient communication system.

Viewed from another aspect, the present disclosure provides a communication system for conveying information from an information source across a communications channel using a joint source channel coding autoencoder, comprising: an encoder neural network of the joint source channel coding autoencoder, the encoder neural network having: an input layer having input nodes corresponding to a sequence of source symbols S^{m}={S₁, S₂, . . . , Sₘ}, the Sᵢ taking values in an alphabet S, received at the input layer from the information source as samples thereof, and a channel input layer coupled to the input layer through one or more neural network layers, the channel input layer having nodes usable to provide values for the Xᵢ of a channel input vector Xⁿ={X₁, X₂, . . . , Xₙ}, the Xᵢ taking values from the available input signal alphabet X of the communications channel, the channel input vector Xⁿ comprising a plurality of signal values X^{p} usable to reconstruct an information source, wherein the number p of the plurality of signal values X^{p} is smaller than the total number n of signal values of the channel input vector Xⁿ, and wherein at least one of the remaining signal values of the channel input vector Xⁿ is usable to increase the quality of the reconstructed information source, and wherein the encoder neural network is configured through training to be usable to map sequences of source symbols S^{m} received from the information source directly to a representation as a channel input vector Xⁿ, usable to drive a transmitter to transmit a corresponding signal over the communications channel; a first decoder neural network and a second decoder neural network of the joint source channel coding autoencoder, each decoder neural network having: a channel output layer having nodes corresponding to a channel output vector Y received from a receiver receiving a signal corresponding to at least the plurality of signal values X^{p} of the channel input vector Xⁿ transmitted by the transmitter and transformed by the communications channel, and an output layer coupled to the channel output layer through one or more neural network layers, having nodes matching those of the input layer of the encoder neural network, wherein the first decoder neural network is configured through training to map the representation of the source symbols as the channel output vector Y transformed by the communications channel to a reconstruction of the source symbols Ŝ^{m} output from the output layer of the joint source channel coding autoencoder, the reconstruction of the source symbols Ŝ^{m} being usable to reconstitute the information source; and wherein the number of signal values of the channel output vector Y received by the first decoder network is more than the number of signal values of the channel output vector Y received by the second decoder neural network.

The plurality of decoder neural networks of the joint source channel coding autoencoder connected to the encoder neural network of the joint source channel coding autoencoder enable a flexible system whereby the encoder neural network can transmit a channel input vector Xⁿ that enables both decoder neural networks to reconstruct the information source even if they receive a differing ‘amount’ (in terms of numbers of signal values) of the signal corresponding to the channel input vector Xⁿ. This may occur, for example, if the decoder neural networks are located in separate receivers and one receiver is capable of receiving more signal values than the other receiver.

The channel input vector Xⁿ comprises a plurality of signal values X^{p} usable to reconstruct an information source, wherein the number p of the plurality of signal values is smaller than the total number n of signal values of the channel input vector Xⁿ, and wherein at least one of the remaining signal values of the channel input vector Xⁿ is usable to increase the quality of the reconstructed information source. Thus, rather than the encoder neural network having to transmit the smallest number of signal values to enable the decoder neural network within the less capable receiver to reconstruct the information source, the encoder neural network can be matched to the more capable receiver, whilst still enabling the less capable receiver to receive the necessary signal. Thus, the encoder neural network can be trained for a plurality of decoder neural networks at a plurality of receivers and can enable reconstruction at all receivers, even if the receivers have different capabilities. In another example, if a receiver is used for fast reconstruction, this receiver can receive and process the plurality p of signal values X^{p} without having to receive and process the remaining symbols.

Moreover, the joint source channel coding autoencoder produces the channel input vector such that the plurality of signal values can be transmitted if the minimum bandwidth is available or transmission. If only the plurality of signal values are transmitted, the receiver can reconstruct the information source at a reasonable quality. If there is additional bandwidth available for transmission, the remaining signal values can be utilised until all the available bandwidth has been used or all the remaining signal values have been transmitted. Thus, the receiver can receive the remaining signal values and combine these with the plurality of signal values X^{p} to produce a better reconstruction of the information source due to receiving more information. This allows for an adaptable system which utilises all available resources. If there is additional bandwidth available, this is exploited to improve the quality of the receiver's reconstruction of the information source.

Such a communication system can be extremely valuable particularly when broadcasting to multiple receivers with different quality requirements and/or channel qualities. Receivers with lower quality reconstruction requirements, e.g., due to lower complexity, lower energy, or lower resolution requirements in their displays, can decode the source based only on the plurality of signal values X^{p}, and they can stop receiving afterwards, saving energy and bandwidth; while receivers with higher quality requirements can listen to all the transmitted signal values of the channel input vector Xⁿ (i.e. the plurality of symbols X^{p} and the remaining symbols), and reconstruct a better quality version of the information source at the expense of additional bandwidth and processing complexity and energy.

Further, such a communication system can be extremely valuable when communicating over a communications channel with variable channel capacity, for example due to motion of the transmitter or receiver in a wireless communications system relative to a base station, competition for channel resource allocation with other transmitters and receivers, and due to local topography and the base station location causing path loss and fading. Here, the communications system can adapt the transmitted channel input signal values representative of the information source to accommodate the variation in channel capacity, such that at times of low channel capacity, only a reduced number of channel input signal values necessary for the information source to be reconstructed with reduced quality may be transmitted by the transmitter over the channel (where resource allocation has been limited) or received by the receiver. Similarly, when the channel capacity is increased, a greater number of channel input signal values may be transmitted or received on the channel allowing the information source to be reconstructed at the receiver with an increased quality. Thus in accordance with this aspect of the present disclosure, the information source may be efficiently transmitted over a communications channel for reconstruction by the receiver using an autoencoder for joint source channel coding that is able to adapt to the varying channel capacity.

The reconstruction of the source symbols Ŝ^{m} of the first decoder neural network may be of a higher quality than the reconstruction of the source symbols Ŝ^{m} of the second decoder neural network.

The plurality of signal values X^{p} usable to reconstruct an information source may be a plurality of consecutive signal values of the channel input vector Xⁿ.

The plurality of signal values X^{p} usable to reconstruct an information source may be a first plurality of consecutive signal values of the channel input vector Xⁿ.

The channel output layer of the first decoder neural network may receive channel output vector Y^{p} from a receiver receiving a signal corresponding to the plurality of signal values X^{p} of the channel input vector Xⁿ.

The channel output layer of the second decoder neural network may receive channel output vector Yⁿ from a receiver receiving a signal corresponding to the channel input vector Xⁿ.

Each of the remaining signal values of the channel input vector Xⁿ, when received in addition to the plurality of signal values X^{p}, may be usable to produce a reconstruction of the source symbols Ŝ^{m} with a higher quality than the reconstruction of the source symbols Ŝ^{m} using the plurality of signal values X^{p}.

A plurality of the remaining signal values of the channel input vector Xⁿ, when received in addition to the plurality of signal values X^{p}, together may be usable to produce a reconstruction of the source symbols Ŝ^{m} with a higher quality than the reconstruction of the source symbols Ŝ^{m} using the plurality of signal values X^{p}.

All of the remaining symbols of the channel input vector Xⁿ may be usable to increase the quality of the reconstructed information source.

The first decoder neural network, the second decoder neural network and the encoder neural network may be trained jointly.

The number of symbols of the reconstruction of the source symbols Ŝ^{m} of the first decoder neural network may be different to the number of symbols of the reconstruction of the source symbols Ŝ^{m} of the second decoder neural network.

The number p of signal values of the plurality of signal values X^{p} may be based on the characteristics of the communications channel and/or capabilities of the receiver comprising the second decoder neural network.

The number n of signal values of the channel input vector Xⁿ may be based on the characteristics of the communications channel and/or capabilities of the receiver comprising the first decoder neural network.

The number p of signal values of the plurality of signal values X^{p} may be such that the information source can be reconstructed at the second decoder neural network.

The sequences of source symbols S^{m} received from the information source may be mapped directly to a representation as a channel input vector Xⁿ.

The joint source channel coding autoencoder may be a joint source channel coding variational autoencoder, wherein the nodes of the channel input layer of the encoder neural network may correspond to a channel input distribution vector Z^{k}={Z₁, Z₂, . . . , Z_{K}}, the Zᵢ taking values for parameters defining a plurality of distributions, each distribution being sampleable to provide possible values for the Xᵢ of the channel input vector Xₙ={X₁, X₂, . . . , Xₙ}, and wherein the encoder neural network may be configured through training to map sequences of source symbols S^{m} received from the information source directly to a representation as a plurality of distributions that provide possible values for the Xᵢ of a channel input vector Xⁿ, the communication system may further comprise: a sampler, configured to produce a channel input vector Xⁿ={X₁, X₂, . . . , Xₙ} in use by sampling the respective distribution for each channel input X defined by the channel input distribution vector Z^{k}={Z₁, Z₂, . . . , Z_{K}} output by the channel input layer of the encoder neural network.

The communications channel may be a noisy communications channel.

The size n of the channel input vector Xⁿ may be smaller than the size m of the source symbols S^{m} and the information source may be compressed during mapping.

The size n of the channel input vector Xⁿ may be based on the channel capacity.

The encoder neural network and decoder neural networks may be trained jointly to minimise the difference between the input and output of the joint source channel coding variational autoencoder.

The encoder neural network and decoder neural networks may be trained jointly based on the type of communications channel.

The encoder neural network and decoder neural networks may be trained jointly based on a model of the communication channel, and the decoder neural networks may be trained further based on the real communication channel using one way communication of known training data samples from the transmitter to the receivers.

The information source may not have been compressed before being input into the joint source channel coding variational autoencoder.

Viewed from another aspect, the present disclosure provides a transmitter device for conveying information from an information source across a communications channel using a joint source channel coding autoencoder comprising: an encoder neural network of a joint source channel coding autoencoder, the encoder neural network comprising: an input layer having input nodes corresponding to a sequence of source symbols S^{m}={S₁, S₂, . . . , Sₘ}, the Sᵢ taking values in a finite alphabet S, received at the input layer from an information source as samples thereof, and a channel input layer coupled to the input layer through one or more neural network layers, the channel input layer having nodes usable to provide values for the Xᵢ of a channel input vector Xⁿ={X₁, X₂, . . . , Xₙ}, the Xᵢ taking values from the available input signal alphabet X of the communications channel, the channel input vector Xⁿ comprising a plurality of signal values X^{p} usable to reconstruct an information source, wherein the number p of the plurality of signal values X^{p} is smaller than the total number n of signal values of the channel input vector Xⁿ, and wherein at least one of the remaining signal values of the channel input vector Xⁿ is usable to increase the quality of the reconstructed information source, and wherein the encoder neural network is configured through training to be usable to map sequences of source symbols S^{m} received from the information source directly to a representation as a channel input vector Xⁿ, usable to drive a transmitter to transmit a corresponding signal over a communications channel; and a transmitter to transmit the channel input vector Xⁿ over the communications channel.

The transmitter device may be in combination with two receiver devices, a first receiver device may comprise the first decoder neural network and a second receiver device may comprise the second decoder neural network.

The transmitter device may be in combination with a receiver device which may comprise the first and second decoder neural networks.

The sequences of source symbols S^{m} received from the information source may be mapped directly to a representation as a channel input vector Xⁿ.

The joint source channel coding autoencoder may be a joint source channel coding variational autoencoder, wherein the nodes of the channel input layer of the encoder neural network may correspond to a channel input distribution vector Z^{k}={Z₁, Z₂, . . . , Z_{K}}, the Zᵢ taking values for parameters defining a plurality of distributions, each distribution being sampleable to provide possible values for the X of the channel input vector Xⁿ={X₁, X₂, . . . , Xₙ}, and wherein the encoder neural network may be configured through training to map sequences of source symbols S^{m} received from the information source directly to a representation as a plurality of distributions that provide possible values for the Xᵢ of a channel input vector Xⁿ, the transmitter device may further comprise: a sampler, configured to produce a channel input vector Xⁿ={X₁, X₂, . . . , Xₙ} in use by sampling the respective distribution for each channel input Xᵢ defined by the channel input distribution vector Z^{k}={Z₁, Z₂, . . . , Z_{K}} output by the channel input layer of the encoder neural network.

Viewed from another aspect, the present disclosure provides a method of an encoder neural network of a joint source channel coding autoencoder for conveying information from an information source across a communications channel, the method comprising: Receiving, at input nodes of an input layer, samples of an information source corresponding to a sequence of source symbols S^{m}={S₁, S₂, . . . , Sₘ}, the Sᵢ taking values in a finite alphabet S; and Mapping the sequence of source symbols S^{m} from the input layer through one or more neural network layers to a channel input layer, the channel input layer having nodes usable to provide values for the Xᵢ of a channel input vector Xⁿ={X₁, X₂, . . . , Xₙ}, the Xᵢ taking values from the available input signal alphabet X of the communications channel, the channel input vector Xⁿ comprising a plurality of signal values X^{p} usable to reconstruct an information source, wherein the number p of the plurality of signal values X^{p} is smaller than the total number n of signal values of the channel input vector Xⁿ, and wherein at least one of the remaining signal values of the channel input vector Xⁿ is usable to increase the quality of the reconstructed information source, and wherein the encoder neural network is configured through training to be usable to map sequences of source symbols S^{m} received from the information source directly to a representation as a channel input vector Xⁿ, usable to drive a transmitter to transmit a corresponding signal over a communications channel.

The joint source channel coding autoencoder may be a joint source channel coding variational autoencoder, wherein the channel input layer has nodes corresponding to a channel input distribution vector Z^{k}={Z₁, Z₂, . . . , Z_{K}}, the Zᵢ taking values for parameters defining a plurality of distributions, each distribution being sampleable to provide possible values for the Xᵢ of a channel input vector Xⁿ, and wherein the encoder neural network is configured through training to map sequences of source symbols Sₘ received from the information source directly to a representation as a plurality of distributions that provide possible values for the Xᵢ of a channel input vector Xₙ.

Viewed from another aspect, the present disclosure provides a training method of a communication system for conveying information from an information source across a communications channel using a joint source channel coding autoencoder comprising an encoder neural network, a first decoder neural network and a second decoder neural network, wherein the number of signal values of the channel output vector Y received by the first decoder network is more than the number of signal values of the channel output vector Y received by the second decoder neural network, the training method comprising: Mapping, by the encoder neural network of the joint source channel coding autoencoder, sequences of source symbols S^{m} received from the information source to a representation as a channel input vector Xⁿ, usable to drive a transmitter to transmit a corresponding signal over the communications channel; For each decoder neural network: Mapping, by the decoder neural network of the joint source channel coding autoencoder, the representation of the source symbols as the channel output vector Y transformed by the communications channel to a reconstruction of the source symbols Ŝ^{m} output from the output layer of the joint source channel coding autoencoder, Comparing the sequence of source symbols S^{m} to the reconstruction of source symbols Ŝ^{m} of the decoder neural network, and Formulating a loss function for the decoder neural network based on the comparison; Amending parameters of the joint source channel coding autoencoder based on the loss functions of the decoder neural networks; and Repeating the above steps until the reconstruction of source symbols Ŝ^{m} at each decoder neural network is usable to reconstitute the information source.

The sequences of source symbols S^{m} received from the information source may be mapped directly to a representation as a channel input vector Xⁿ.

The joint source channel coding autoencoder may be a joint source channel coding variational autoencoder, and the sequences of source symbols S^{m} received from the information source may be mapped directly to a representation as a plurality of distributions that provide possible values for the Xᵢ of a channel input vector Xⁿ.

The steps may be repeated until the reconstruction of source symbols Ŝ^{m} at the second decoder neural network is usable to reconstitute the information source and the reconstruction of source symbols Ŝ^{m} at the first decoder neural network is of a higher quality than the reconstruction of source symbols Ŝ^{m} at the second decoder neural network.

The parameters may be amended based on the weighted sum of the loss functions.

The weighting of each of the loss functions may be based on the desired reconstruction quality of the first decoder neural network and the second decoder neural network.

The weighting of each of the loss functions may be based on balancing the reconstruction qualities of the first decoder neural network and the second decoder neural network.

The weighting of the loss functions may be amended to balance the reconstruction qualities of the first decoder neural network and the second decoder neural network.

The weighting of each of the loss functions may be based on the requirements of the receiver of the first decoder neural network and the receiver of the second decoder neural network.

The weighting of each of the loss functions may be based on the quality of the communications channel between the encoder neural network and the first decoder neural network and the quality of the communications channel between the encoder neural network and the second decoder neural network.

Viewed from another aspect, the present disclosure provides a computer-readable storage medium comprising instructions which, when executed by a computer, cause the computer to carry out the steps of the method of the encoder neural network.

Viewed from another aspect, the present disclosure provides a computer-readable storage medium comprising instructions which, when executed by a computer, cause the computer to carry out the steps of the training method.

As indicated above, digital communication systems with source coding and separate channel coding suffer from a threshold effect, where the input source cannot be reconstructed as soon as the noise goes above the target noise level. This is because, if the correct channel codeword cannot be decoded, this also leads to an error in the source decoder and causes the reconstruction of the signal to be completely meaningless rather than distorted. Thus on noisy channels, particularly where signal drop offs are not desirable, joint source channel coding can be problematic.

It is in this context that the presently disclosed joint source channel coding variational autoencoder for use in a communication system for conveying information from an information source across a communications channel has been devised. In consideration of the context of the above background, the present inventors have realised that using a joint source channel coding variational autoencoder to convey information from an information source across a communications channel would provide an advantageous means of providing a simple and flexible communication system addressing the limitations of current communication systems.

Thus, viewed from another aspect, the present disclosure provides a communication system for conveying information from an information source across a communications channel using a joint source channel coding variational autoencoder, comprising an encoder neural network of the joint source channel coding variational autoencoder, the encoder neural network having an input layer having input nodes corresponding to a sequence of source symbols S^{m}={S₁, S₂, . . . , Sₘ}, the Sᵢ taking values in a finite alphabet S, received at the input layer from the information source as samples thereof, and a channel input layer coupled to the input layer through one or more neural network layers, the channel input layer having nodes corresponding to a channel input distribution vector Z^{k}={Z₁, Z₂, . . . , Z_{K}}, the Zᵢ taking values for parameters defining a plurality of distributions, each distribution being sampleable to provide possible values for the Xᵢ of a channel input vector Xⁿ={X₁, X₂, . . . , Xₙ}, the Xᵢ taking values from the available input signal values of the communications channel, wherein the encoder neural network is configured through training to map sequences of source symbols S^{m} received from the information source directly to a representation as a plurality of distributions that provide possible values for the Xᵢ of a channel input vector Xⁿ, usable to drive a transmitter to transmit a corresponding signal over the communications channel; a sampler, configured to produce a channel input vector Xⁿ={X₁, X₂, . . . , Xₙ} in use by sampling the respective distribution for each channel input X defined by the channel input distribution vector Z^{k}={Z₁, Z₂, . . . , Z_{K}} output by the channel input layer of the encoder neural network; and a decoder neural network of the joint source channel coding variational autoencoder, the decoder neural network having a channel output layer having nodes corresponding to a channel output vector Yⁿ received from a receiver receiving the signal Xⁿ transmitted by the transmitter and transformed by the communications channel, and an output layer coupled to the channel output layer through one or more neural network layers, having nodes matching those of the input layer of the encoder neural network, wherein the decoder neural network is configured through training to map the representation of the source symbols as the channel output vector Yⁿ transformed by the communications channel to a reconstruction of the source symbols Ŝ^{m} output from the output layer of the joint source channel coding variational autoencoder, the reconstruction of the source symbols Ŝ^{m} being usable to reconstitute the information source.

In accordance with the presently disclosed communication system, a variational autoencoder is provided that is trained to perform joint source and channel coding (referred to as “joint source channel coding”) in which the information source, or sequences of raw, unencoded symbols generated thereby, are mapped by an encoder neural network to an output distribution sampleable (e.g. probabilistically) to directly derive the signal values of a channel input vector to drive a transmitter to transmit the encoded data over the communications channel. That is, for example, the encoder neural network may map a sequence of input symbols representative of an uncompressed frame of a video stream to parameters (such as mean and variance) for defining distributions (for example, gaussian distributions) for each signal value of a channel input vector (for example, the I and Q values for a Quadrature Modulation transmission scheme). Then, by taking a sample of these distributions, the I-Q signal values for transmission can be derived. On receipt at the receiver of a transmitted channel input vector having noise added by the communications channel, this is directly decoded using a decoder neural network trained together with the encoder neural network, to recover a representation of the original source symbols.

Further, the encoder neural network of the present disclosure comprises a channel input layer having nodes defining a plurality of distributions, which are then sampled to provide the channel input vector Xⁿ usable to drive a transmitter to transmit a corresponding signal over the communications channel. Therefore, instead of generating specific channel input values for specific inputs, where similar input values may be mapped to differing channel input values, by imposing a prior distribution, the encoder neural network is steered towards mapping similar input values to similar channel inputs. This means that, despite the noise added, the reconstruction of the input will be of a reasonable quality. This also enables graceful degradation of the reconstructed input values, whereby as the noise of the communications channel increases, the difference between the sequence of source symbols and the reconstruction of the source symbols increases, gradually decreasing the quality of the reconstruction of the information source. In this way, signal drop outs can be avoided in noisy communications channels, which is important where high reliability of transmission and reception is desired.

Thus, there is provided a simple and flexible communications system with improved source reconstruction.

The plurality of distributions may have the same distribution type.

The communications channel may be a noisy communications channel.

The distribution type of the plurality of distributions may be based on the characteristics of the communication channel.

The distribution type may be the optimal input distribution for the channel.

The communications channel may be modelled as a Gaussian channel, the plurality of distributions may be Gaussian distributions and the parameters defining the distributions may be the mean and standard deviation.

The size n of the channel input vector Xⁿ may be smaller than the size m of the source symbols S^{m} and the information source may be compressed during mapping.

The size n of the channel input vector Xⁿ may be based on the channel capacity.

The information source may be an image and the sequence of source symbols S^{m} may represent pixels of the image.

Each of the plurality of distributions may represent a feature of the image.

The encoder neural network and decoder neural network may be trained jointly.

The encoder neural network and decoder neural network may be trained jointly to minimise the difference between the input and output of the joint source channel coding variational autoencoder.

The encoder neural network may be trained to learn the parameters of the plurality of distributions.

The encoder neural network and decoder neural network may be trained jointly using the backpropagation algorithm or the stochastic gradient descent training algorithm.

The encoder neural network and decoder neural network may be trained jointly based on the type of communications channel.

The encoder neural network and decoder neural network may be trained jointly based on a model of the communication channel, and the decoder neural network may be trained further based on the real communication channel using one way communication of known training data samples from the transmitter to the receiver.

The encoder neural network and decoder neural network may be trained to meet channel input constraints.

The encoder neural network and decoder neural network may be trained jointly based on the type of information source, or for a given information source.

The Xᵢ of the channel input vector Xⁿ may belong to a set of complex numbers, corresponding to the I and Q components.

Similar information sources may be mapped to similar channel inputs.

The channel input vector Xⁿ may comprise one sample from each distribution of the plurality of distributions.

The encoder neural network and decoder neural network may be trained jointly based on the measure of distance from a target distribution to the plurality of distributions.

The distance from the target distribution may be measured using KL divergence.

The channel input layer may be coupled to the input layer through at least five neural network layers.

The difference between the sequence of source symbols S^{m} and the reconstruction of the source symbols Ŝ^{m} may increase as the noise of the communications channel increases.

The information source may not have been compressed before being input into the joint source channel coding variational autoencoder.

Viewed from another aspect, the present disclosure provides an encoder neural network of a joint source channel coding variational autoencoder, the encoder neural network comprising: an input layer having input nodes corresponding to a sequence of source symbols S^{m}={S₁, S₂, . . . , Sₘ}, the Sᵢ taking values in a finite alphabet S, received at the input layer from an information source as samples thereof, and a channel input layer coupled to the input layer through one or more neural network layers, the channel input layer having nodes corresponding to a channel input distribution vector Z^{k}={Z₁, Z₂, . . . , Z_{K}}, the Zᵢ taking values for parameters defining a plurality of distributions, each distribution being sampleable to provide possible values for the X of a channel input vector Xⁿ={X₁, X₂, . . . , Xₙ}, the X taking values from the available input signal values of the communications channel, wherein the encoder neural network is configured through training to map sequences of source symbols S^{m} received from the information source directly to a representation as a plurality of distributions that provide possible values for the Xᵢ of a channel input vector Xⁿ, usable to drive a transmitter to transmit a corresponding signal over a communications channel.

Viewed from another aspect, the present disclosure provides a transmitter device comprising: an encoder neural network of a joint source channel coding variational autoencoder, the encoder neural network comprising: an input layer having input nodes corresponding to a sequence of source symbols S^{m}={S₁, S₂, . . . , Sₘ}, the Sᵢ taking values in a finite alphabet S, received at the input layer from an information source as samples thereof, and a channel input layer coupled to the input layer through one or more neural network layers, the channel input layer having nodes corresponding to a channel input distribution vector Z^{k}={Z₁, Z₂, . . . , Z_{K}}, the Zᵢ taking values for parameters defining a plurality of distributions, each distribution being sampleable to provide possible values for the X of a channel input vector Xⁿ={X₁, X₂, . . . , Xₙ}, the X taking values from the available input signal values of the communications channel, wherein the encoder neural network is configured through training to map sequences of source symbols S^{m} received from the information source directly to a representation as a plurality of distributions that provide possible values for the X of a channel input vector Xⁿ, usable to drive a transmitter to transmit a corresponding signal over a communications channel; a sampler, configured to produce a channel input vector Xⁿ={X₁, X₂, . . . , Xₙ} in use by sampling the respective distribution for each channel input X defined by the channel input distribution vector Z^{k}={Z₁, Z₂, . . . , Z_{K}} output by the channel input layer of the encoder neural network; and a transmitter to transmit the channel input vector Xⁿ over the communications channel.

The transmitter device may comprise a plurality of said encoder neural networks, each trained for joint source channel coding of different given information sources or types of information source, for transmission to and decoding thereof at a receiver.

Viewed from another aspect, the present disclosure provides a method of an encoder neural network of a joint source channel coding variational autoencoder for conveying information from an information source across a communications channel, the method comprising: receiving, at input nodes of an input layer, samples of an information source corresponding to a sequence of source symbols S^{m}={S₁, S₂, . . . , Sₘ}, the Sᵢ taking values in a finite alphabet S; and Mapping the sequence of source symbols S^{m} from the input layer through one or more neural network layers to a channel input layer, the channel input layer having nodes corresponding to a channel input distribution vector Z^{k}={Z₁, Z₂, . . . , Z_{K}}, the Zᵢ taking values for parameters defining a plurality of distributions, each distribution being sampleable to provide possible values for the X of a channel input vector Xⁿ={X₁, X₂, . . . , Xₙ}, the Xᵢ taking values from the available input signal values of the communications channel, wherein the encoder neural network is configured through training to map sequences of source symbols S^{m} received from the information source directly to a representation as a plurality of distributions that provide possible values for the Xᵢ of a channel input vector Xⁿ, usable to drive a transmitter to transmit a corresponding signal over a communications channel.

Viewed from another aspect, the present disclosure provides a training method of a communication system for conveying information from an information source across a communications channel using a joint source channel coding variational autoencoder, the training method comprising: mapping, by an encoder neural network of a joint source channel coding variational autoencoder, sequences of source symbols S^{m} received from the information source directly to a representation as a plurality of distributions that provide possible values for the Xᵢ of a channel input vector Xⁿ, usable to drive a transmitter to transmit a corresponding signal over the communications channel; mapping, by a decoder neural network of the joint source channel coding variational autoencoder, the representation of the source symbols as the channel output vector Yⁿ transformed by the communications channel to a reconstruction of the source symbols S^{m} output from the output layer of the joint source channel coding variational autoencoder; comparing the sequences of source symbols S^{m} to the reconstruction of source symbols Ŝ^{m}; amending parameters of the joint source channel coding variational autoencoder based on the comparison; and repeating the above steps until the reconstruction of source symbols Ŝ^{m} is usable to reconstitute the information source.

Viewed from another aspect, the present disclosure provides a computer-readable storage medium comprising instructions which, when executed by a computer, cause the computer to carry out the steps of the method of the encoder neural network.

Viewed from another aspect, the present disclosure provides a computer-readable storage medium comprising instructions which, when executed by a computer, cause the computer to carry out the steps of the training method.

The communication system may be as described hereinbefore.

It will be appreciated from the foregoing disclosure and the following detailed description of the examples that certain features and implementations described as being optional in relation to any given aspect of the disclosure set out above should be understood by the reader as being disclosed also in combination with the other aspects of the present disclosure, where applicable. Similarly, it will be appreciated that any attendant advantages described in relation to any given aspect of the disclosure set out above should be understood by the reader as being disclosed as advantages of the other aspects of the present disclosure, where applicable. That is, the description of optional features and advantages in relation to a specific aspect of the disclosure above is not limiting, and it should be understood that the disclosures of these optional features and advantages are intended to relate to all aspects of the disclosure in combination, where such combination is applicable.

### BRIEF DESCRIPTION OF THE DRAWINGS

Embodiments of the invention are further described hereinafter with reference to the accompanying drawings, in which:

FIG. 1 provides an example illustration of a neural network.

FIG. 2 provides an example of a joint source channel coding autoencoder.

FIG. 3 provides an illustration of a communication system according to an example.

FIG. 4 provides an illustration of a transmitter device according to an example.

FIG. 5 provides an illustration of a transmitter device according to another example.

FIG. 6 provides an illustration of a receiver device according to an example.

FIG. 7 provides another example of a joint source channel coding autoencoder.

FIG. 8 provides an illustration of a communication system according to another example.

FIG. 9 provides an example flowchart of a method of an encoder neural network.

FIG. 10 provides an example flowchart of a training method of a communication system.

FIG. 11 provides an example of a joint source channel coding variational autoencoder.

FIG. 12 provides another illustration of a communication system according to an example.

FIG. 13 provides an illustration of the sampler according to an example.

FIG. 14 provides another example flowchart of a method of an encoder neural network.

FIG. 15 provides another example flowchart of a training method of a communication system.

FIG. 16 provides another illustration of a transmitter device according to an example.

FIG. 17 is a schematic diagram showing a computer according to an example.

FIG. 18 provides another illustration of a communication system according to an example.

### DETAILED DESCRIPTION

The present disclosure describes a communication system for conveying information from an information source across a communications channel using a joint source channel coding autoencoder, the communication system producing a high fidelity reconstruction of the information source for different information sources and different channel noise.

The communications channel is used to convey information from one or more transmitters to one or more receivers. The channel may be a physical connection, e.g. a wire, or a wireless connection such as a radio channel. The communications channel may be an optical channel or a Bluetooth channel. There is an upper limit to the performance of a communication system which depends on the system specified. In addition, there is also a specific upper limit for all communication systems which no system can exceed. This fundamental upper limit is an upper bound to the maximum achievable rate of reliable communication over a noisy channel and is known as Shannon's capacity.

The communications channel, including the noise associated with such a channel, is modelled and defined by its characteristics and statistical properties. Channel characteristics can be identified by comparing the input and output of the channel, the output of which is likely to be a randomly distorted version of the input. The distortion indicates channel statistics such as additive noise, or other imperfections in the communication medium such as fading or synchronization errors between the transmitter and the receiver. Channel characteristics include the distribution model of the channel noise, slow fading and fast fading. Common channel models include binary symmetric channel and additive white Gaussian noise (AWGN) channel.

Neural networks are machine learning models that employ multiple layers of nonlinear units (known as artificial “neurons”) to generate an output from an input. Neural networks learn through training to produce the optimum output. They help to group unlabelled data according to similarities and can classify data when they have a labelled dataset to train on. Neural networks may be composed of several layers, each layer formed from nodes. Neural networks can have one or more hidden layers in addition to the input layer and the output layer. The output of each layer is used as the input to the next layer (the next hidden layer or the output layer) in the network. Each layer generates an output from its input using a set of parameters, which are optimized during the training stage. For example, each layer comprises a set of nodes, the nodes having learnable biases and their inputs having learnable weights. Learning algorithms can automatically tune the weights and biases of nodes of a neural network to optimise the output.

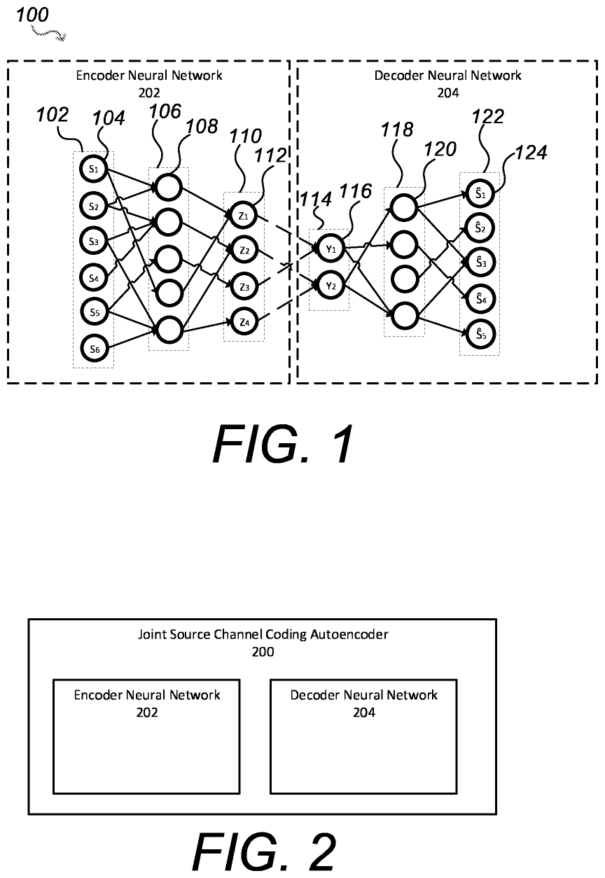

FIG. 1 provides an example illustration of a neural network 100. Neural network 100 has a plurality of nodes and connections. The nodes are arranged to be in layers. The layers are illustrated in dashed lines to show that they are simply groupings of nodes rather than being separate objects. The neural network 100 comprises an input layer 102 comprising a plurality of input nodes 104 and an output layer 122 comprising a plurality of output nodes 124. The neural network 100 further comprises a plurality of hidden layers 106, 110, 114, 118 comprising a plurality of nodes 108, 112, 116, 120. The arrows between nodes illustrate connections. The nodes 104 of the input layer 102 are connected to nodes 108 of the hidden layer 106. The nodes 108 of the hidden layer 106 are connected to nodes 112 of the hidden layer 110. The nodes 112 of the hidden layer 110 are connected to nodes 116 of the hidden layer 114. The nodes 116 of the hidden layer 114 are connected to nodes 120 of the hidden layer 118. The nodes 120 of the hidden layer 118 are connected to the nodes 124 of the output layer 122. The connection between nodes means that the output of one node is the input to the next node. The output of the node may be a numerical value. The connection may have a weight associated with it which adjusts the output value of the previous node before inputting into the next node.

Although four hidden layers are illustrated in the figure, a neural network may comprise any number of hidden layers. Moreover, although a certain number of nodes is shown for each layer, this is merely for illustration and a layer may comprise any number of nodes. The neural network layers may also be three dimensional.

An autoencoder is a neural network that is trained to copy its input to its output. Autoencoders can provide dimensionality reduction at a hidden layer arranged to have fewer nodes than the input layer. Autoencoders also provide feature learning. An autoencoder includes an encoder neural network and a decoder neural network. These two networks are trained jointly to generate a reconstruction of the input. Typically, either the output of the encoder network has a lower dimension than the input, so that a low-dimensional representation of the input is learned; or, a loss function that imposes certain properties on the encoder output is used, that can act as a regularizer to prevent the network from learning the identity function.

In an autoencoder, the goal of the system is to make sure that each input can be regenerated based on the encoder output. The encoder therefore tries to learn the most essential features of input data samples from an information source. As the autoencoder is trained to learn the input data samples from an information source, for multiple input data sources, multiple autoencoders each trained for their specific input samples provide a highly efficient system that is adaptable for multiple different input data sources. The autoencoder will be explained further in the following figures.

The autoencoder in accordance with examples of the present disclosure can be used in a communication system for conveying information from an information source across a communications channel. The encoder neural network of the autoencoder can replace the traditional source encoder and channel encoder. The encoder neural network maps the signal directly to input signal values in the channel input layer, where it is transmitted over the communications channel. As will be explained in more detail below, the autoencoder may be a variational autoencoder in which the encoder neural network maps the signal directly to parameters of distributions in the input signal values of the channel input layer, where the distributions are sampled to produce the channel input vector that is transmitted over the communications channel. The decoder neural network of the autoencoder can replace the traditional source decoder and channel decoder. The decoder neural network receives the output of the communications channel and reconstructs the signal. The encoder neural network and decoder neural network are trained to undo the effect of the channel on the signal, such as the effect of the channel noise of the signal. The encoder neural network and decoder neural network can also be trained to learn a representation of the source signal and recover the input with the highest fidelity possible. Further, as the neural networks are trained to optimise the mapping, the efficiency of the transmission of the information source over the communications channel can be greater than in separate source and channel coding, where the separate removal and subsequent addition of redundancy may be inherently inefficient for transferring the data.

Thus, the encoder and decoder neural networks can be used as a form of joint source channel coding. This provides simplicity over having two separate systems for encoding and two separate systems for decoding. However, the limitations of the joint source channel coding techniques as mentioned above are removed. In particular, an autoencoder used for joint source channel coding, herein referred to as the joint source channel coding autoencoder, can be trained for use with different channels and different input sources. Thus, using neural networks for conveying information across a channel enables a high degree of freedom.

### Joint Source Channel Coding Autoencoder

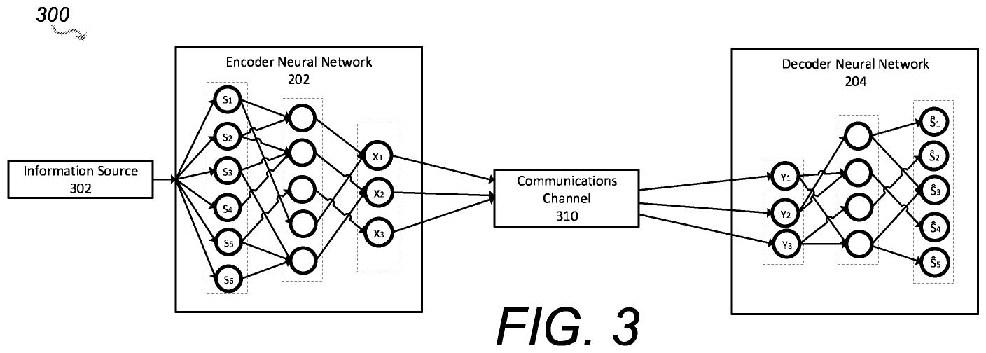

FIG. 2 provides an example of a joint source channel coding autoencoder 200. The joint source channel coding autoencoder 200 comprises an encoder neural network 202 and a decoder neural network 204. The encoder neural network and decoder neural network may be deep and/or recurrent.

For example, with reference to FIG. 1, the neural network of FIG. 1 may be a joint source channel coding autoencoder 200. The encoder neural network 202 of the joint source channel coding autoencoder 200 may be formed from layers 102, 106 and 110. The decoder neural network 204 of the joint source channel coding autoencoder 200 may be formed from layers 114, 118 and 122.

With reference to FIGS. 1 and 2, the encoder neural network 202 of the joint source channel coding autoencoder 200 has an input layer 102 having input nodes 104 corresponding to a sequence of source symbols S^{m}={S₁, S₂, . . . , Sₘ}, the Sᵢ taking values in a finite alphabet S, received at the input layer 102 from an information source as samples thereof. The encoder neural network 202 also has a channel input layer 110 coupled to the input layer through one or more neural network layers 106, the channel input layer 110 having nodes 112 usable to provide values for the Xᵢ of a channel input vector Xⁿ={X₁, X₂, . . . , Xₙ}, the Xᵢ taking values from the available input signal values of a communications channel.

The encoder neural network 202 is configured through training to be usable to map sequences of source symbols S^{m} received from the information source directly to a representation as a channel input vector Xⁿ, usable to drive a transmitter to transmit a corresponding signal over the communications channel.

In an example, the channel input layer 110 is coupled to the input layer 102 through at least five neural network layers 106. The encoder neural network 202 may directly map the input nodes 104 at the input layer 102, corresponding to a sequence of source symbols S^{m}, to the nodes 112 of the channel input layer 110, corresponding to a channel input vector Xⁿ, through the neural network.

In the communication system, for a wireless communications channel in accordance with an example, each input signal Xᵢ of the channel input vector Xⁿ may belong to a set of complex numbers, corresponding to the I and Q components. In an example, the encoder neural network 202 of the joint source channel coding autoencoder 200 may perform bandwidth compression. For example, the encoder neural network 202 may compress the information source during mapping such that the size n of the channel input vector Xⁿ is smaller than the size m of the source symbols S^{m}. Alternatively, the joint source channel coding autoencoder 200 may perform a bandwidth expansion, where the size n of the channel input vector Xⁿ is larger than the size m of the source symbols S^{m}.

When the neural network of FIG. 1 is modelled as a joint source channel coding autoencoder, channel input layer 110 and channel output layer 114 are not directly connected, as indicated by the dashed arrows connecting the nodes of these layers. The communications channel is between channel input layer 110 and channel output layer 114. Thus, the values output from the encoder neural network may not be equal to the values input into the decoder neural network (for example due to noise on the communications channel).

The decoder neural network 204 is to map the channel output signals received at the channel output layer 114 to a reconstructed version of the channel input vector Ŝ^{m}. The decoder neural network 204 may be a standard decoder of an autoencoder. The mapping may be a deterministic mapping. (Alternatively, where the autoencoder is a variational autoencoder) the mapping may be a probabilistic mapping.

The decoder neural network 204 of the joint source channel coding autoencoder 200 has a channel output layer 114 having nodes 116 corresponding to a channel output vector Yⁿ received from a receiver receiving the signal Xⁿ transmitted by the transmitter and transformed by the communications channel. The decoder neural network 204 also has an output layer 122 coupled to the channel output layer 114 through one or more neural network layers 118, having nodes 124 matching those of the input layer 104 of the encoder neural network.

The decoder neural network 204 is configured through training to map the representation of the source symbols as the channel output vector Yⁿ transformed by the communications channel to a reconstruction of the source symbols Ŝ^{m} output from the output layer of the joint source channel coding autoencoder 200, the reconstruction of the source symbols Ŝ^{m} being usable to reconstitute the information source.

In an example, the channel output layer 114 is coupled to the output layer 122 through at least five neural network layers 118. The decoder neural network 204 may directly map the nodes 116 at the channel output layer 114, corresponding to a channel output vector Yⁿ, to the nodes 124 of the output layer 122, corresponding to a reconstruction of the source symbols Ŝ^{m}, through the neural network.

The encoder neural network 202 and decoder neural network 204 may have any number of layers and each layer may comprise any number of nodes. In an example, the output layer of the encoder neural network 202 has the same number of nodes as the input layer of the decoder neural network 204. In another example, the input layer of the encoder neural network 202 has the same number of nodes as the output layer of the decoder neural network 204.

In an example, the size n of the channel input vector Xⁿ is based on the channel capacity or the channel resources allocated for use by the transmitter (for example, the radio resources, or OFDM symbols, allocated to a radio bearer for a transmitter terminal for digital (e.g. QAM) modulation thereby in an LTE communication system). Alternatively or additionally, the size n of the channel input vector Xⁿ may be based on the size m of the source symbols S^{m} or the size m of the reconstruction of the source symbols Ŝ^{m}. In an example, the size of the source symbols S^{m} is not equal to the size of the reconstruction of the source symbols Ŝ^{m}. The size m of the reconstruction of the source symbols Ŝ^{m} may be larger than the size n of the channel output vector Yⁿ. The size n of the channel input vector Xⁿ may be equal to the size n of the channel output vector Yⁿ. In another example, the size n of the channel input vector Xⁿ may be different from the size n of the channel output vector Yⁿ for example, for a multiple input multiple output channel.

FIG. 3 provides an illustration of a communication system 300 according to an example. The communication system comprises an information source 302. The information source 302 may be any information source. For example, the information source 302 may be a discrete or continuous information source. If the information source 302 is a continuous information source, it may be sampled before being input into the encoder neural network 202. In an example, the information source 302 is an image and the sequence of source symbols S^{m} are pixels of the image. For example, when the image is a colour image, the sequence of source symbols S^{m} may be a matrix having three values for each pixel, such as the red, green and blue values when the image has RGB components.

In another example, the information source is text, video or sensor measurements. The information source may comprise a structured data set. In an example, the information source is raw, i.e. the information source has not been compressed before being input into the joint source channel coding autoencoder 200.

The information source is input into input layer 102 of the encoder neural network 202 of the joint source channel coding autoencoder 200. The encoder neural network 202 is described above with reference to FIGS. 1 and 2. The encoder neural network 202 has a channel input layer 110 coupled to the input layer 102 through one or more neural network layers 106, the channel input layer 110 having nodes 112 corresponding to a channel input vector Xⁿ={X₁, X₂, . . . , Xₙ}, the Xᵢ taking values from the available input signal alphabet X of the communications channel.

The encoder neural network 202 of the joint source channel coding autoencoder 200 receives, at input nodes of an input layer 102, samples of an information source corresponding to a sequence of source symbols S^{m}={S₁, S₂, . . . , Sₘ}, the Sᵢ taking values in a finite alphabet S. Next, the encoder neural network 202 maps the sequence of source symbols S^{m} from the input layer through one or more neural network layers 106 to a channel input layer 110, the channel input layer 110 having nodes 112 usable to provide values for the Xᵢ of a channel input vector Xⁿ={X₁, X₂, . . . , Xₙ}, the Xᵢ taking values from the available input signal alphabet X of the communications channel 310. The encoder neural network 202 is configured through training to be usable to map sequences of source symbols S^{m} received from the information source 302 directly to a representation as a channel input vector Xⁿ, usable to drive a transmitter to transmit a corresponding signal over a communications channel 310.

In an example, the channel input layer 110 has nodes corresponding to channel input vector Xⁿ and the sequences of source symbols S^{m} are mapped directly to a representation as the channel input vector Xⁿ. The values of the channel input vector Xⁿ may need to be normalized before being input into the communications channel 310 to comply with average input power constraints.

The channel input vector Xⁿ may be transmitted across communications channel 310. Communications channel 310 may be any type of communications channel. The types of communication channels and associated characteristics and statistical properties have been previously explained, and the communications channel 310 may be any of those previously explained. For example, communications channel 310 may be a noisy communications channel. The noisy communications channel is specified by its input and output, and the output may be a randomly distorted version of the input. This distortion may be at least partially caused by noise and may also be caused by other imperfections in the communication medium such as fading or synchronization errors between the transmitter and the receiver.

In an example, the communication channel transforms the channel input vector Xⁿ into the channel output vector Yⁿ in a random manner. If the channel is memoryless, then the distribution of the channel output conditioned on the channel input is given by

$${P}_{Y} {n}_{\vert X} n ( {y}^{n} \vert {x}^{n} ) = {\sum }_{i = 1}^{n} {P}_{Y \vert X} ( {y}_{i} \vert {x}_{i} )$$

However, the channel may have memory, which means that the output symbol at time i may depend on the channel inputs before time i as well, or the channel behaviour may change over time, for example, due to bursty noise. Typical digital communication systems use channel codes that are optimized for independent identically distributed (IID) channels.

The quality of the reconstruction of the input vector Ŝ^{m} is measured using a prespecified distortion measure. In most cases an additive distortion measure is considered, where the distortion is given by the sum of the distortions of individual source samples. For example

$$D ( {S}^{m} , {\hat{S}}^{m} ) = \frac{1}{m} {\sum }_{i = 1}^{m} d ( {S}_{i} , {\hat{S}}_{l} )$$

In case of image transmission, the distortion may be measured by the average squared error distortion.

The communications channel 310 may be an additive white Gaussian noise (AWGN) channel. Channel output vector Yⁿ may be a distorted version of the channel input vector.

As the input to the decoder neural network becomes less similar to the output of the encoder neural network, the Bit Error Rate in the reconstruction of the information source increases.

The decoder neural network receives the channel output vector. The decoder neural network 204 is described above with reference to FIGS. 1 and 2. Thus the decoder neural network of the communication system produces a reconstruction of the source symbols Ŝ^{m} usable to reconstitute the information source 302.

In an example, communication system 300 is a practical communication system. In this example, an input cost constraint is applied on the channel input, due to the limited energy of the transmitter or interference limitations. The cost function assigns a specific cost to each possible channel input symbol. The average cost constraint of P requires that every channel input vector satisfies:

$$\frac{1}{n} {\sum }_{i = 1}^{n} c ( {X}_{i} ) \leq P$$

In a wireless communication system, the input cost constraint may be the transmission power, given by c(X)=|X|². The cost function enables error minimisation between the information source and the reconstructed information source.

The encoder neural network 202 and decoder neural network 204 of the joint source channel coding autoencoder 200 may be trained jointly to obtain a neural network capable of sufficiently reconstructing the information source 302. For example, they may be trained jointly based on the characteristics of the communication channel, based on the type of information source, for a given information source and/or to meet channel input constraints. The encoder neural network 202 and decoder neural network 204 of the joint source channel coding autoencoder 200 may be trained jointly using performance measures. One performance measure may be the loss function.

The encoder neural network 202 and decoder neural network 204 of the joint source channel coding autoencoder 200 may be trained jointly to minimise the difference between the input and output of the joint source channel coding autoencoder 200. The difference between the input and output of the joint source channel coding autoencoder 200 may be another performance measure. The difference may be measured by observing the similarity between the information source and the reconstructed information source.

The encoder neural network 202 and decoder neural network 204 may be trained jointly using the backpropagation algorithm or the stochastic gradient descent training algorithm. In an example, in addition to being trained jointly, the decoder neural network may be trained further based on the real communication channel 310 using one way communication of known training data samples from the transmitter to the receiver. The real communication channel is the physical communication channel rather than a model of the channel characteristics that may be used on a computer for simulation. Known training data samples may be chosen for their ability to train the neural network of the joint source channel coding autoencoder 200. Known training data samples may be used for all joint source channel coding autoencoders 200 or may be chosen based on the information source 302 to be input into the joint source channel coding autoencoder 200. Alternatively, the encoder neural network 202 and decoder neural network 204 may be trained jointly using a known training set, such as the MNIST data set.

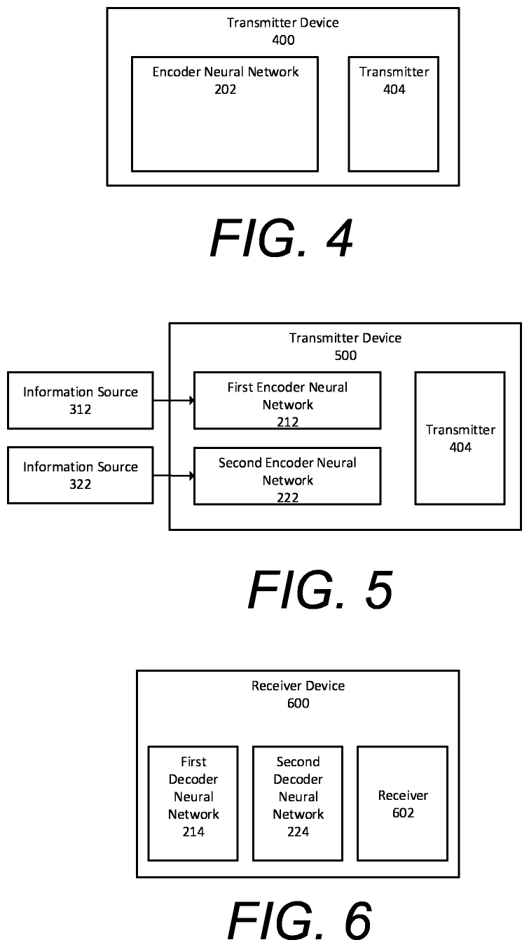

FIG. 4 provides an example of a transmitter device 400. The transmitter device 400 comprises an encoder neural network 202 of a joint source channel coding autoencoder 200 and a transmitter 404. The encoder neural network 202 of the transmitter device 400 comprises an input layer 102 having input nodes 104 corresponding to a sequence of source symbols S^{m}={S₁, S₂, . . . , Sₘ}, the Sᵢ taking values in a finite alphabet S, received at the input layer 102 from an information source 302 as samples thereof, and a channel input layer 110 coupled to the input layer 102 through one or more neural network layers 106, the channel input layer having nodes usable to provide values for the X of a channel input vector Xⁿ={X₁, X₂, . . . , Xₙ}, the X taking values from the available input signal alphabet X of the communications channel, wherein the encoder neural network is configured through training to be usable to map sequences of source symbols S^{m} received from the information source directly to a representation as a channel input vector Xⁿ, usable to drive a transmitter to transmit a corresponding signal over a communications channel. The transmitter 404 is to transmit the channel input vector Xⁿ over the communications channel.

### Transmitter/Receiver Having Multiple Joint Source Channel Coding Autoencoders for Multiple Information Sources

FIG. 5 provides another example of a transmitter device 500. The transmitter device 500 comprises a plurality of encoder neural networks 212, 222, each encoder neural network 212, 222 of a joint source channel coding autoencoder 200, and each encoder neural network 212, 222 trained to receive a different information source 312, 322 or a different type of information source 312, 322. Each encoder neural network 212, 222 comprises: an input layer 102 having input nodes 104 corresponding to a sequence of source symbols S^{m}={S₁, S₂, . . . , Sₘ}, the Sᵢ taking values in a finite alphabet S, received at the input layer from an information source as samples thereof, and a channel input layer 110 coupled to the input layer 102 through one or more neural network layers 106, the channel input layer 110 having nodes 112 usable to provide values for the Xᵢ of a channel input vector Xⁿ={X₁, X₂, . . . , Xₙ}, the Xᵢ taking values from the available input signal alphabet X of the communications channel 310, wherein the encoder neural network 212, 222 is configured through training to be usable to map sequences of source symbols S^{m} received from the information source 312, 322 directly to a representation as a channel input vector Xⁿ, usable to drive a transmitter 404 to transmit a corresponding signal over a communications channel 310.

The transmitter device 500 also comprises a transmitter 404 to transmit the channel input vector Xⁿ over the communications channel 310. The channel input vector Xⁿ may include signal values Xⁱ encoded by one or both encoder neural networks, such that the transmitter device 500 may transmit at the same time signal values from multiple different encoder neural networks to send over the communications channel multiple different information sources using joint source channel coding. The transmitter device 400 may also comprise a plurality of transmitters to transmit multiple channel input vectors Xⁿ for the plurality of encoder neural networks 212, 222 over the communications channel 310. The transmitter 404 may transmit the channel input vector Xⁿ of each encoder neural network simultaneously and/or at a different frequency over the communications channel.

The transmitter device 500 comprises a first encoder neural network 212 and a second encoder neural network 222. Although two encoder neural networks are illustrated, the transmitter device 500 may comprise any number of encoder neural networks. The first encoder neural network 212 and second encoder neural network 222 are examples of encoder neural network 202 of FIGS. 1 and 2. The first encoder neural network 212 is part of a joint source channel coding autoencoder. The second encoder neural network 212 is part of a joint source channel coding autoencoder. Each encoder neural network may be of a different joint source channel coding autoencoder. The joint source channel coding autoencoder comprising the first encoder neural network 212 and the joint source channel coding autoencoder comprising the second encoder neural network 222 are examples of joint source channel coding autoencoder 200 of FIG. 2. Each encoder neural network may have a different number of nodes at the channel input layer 102. In an example, the channel input layer 110 of one or more encoder neural networks 212, 222 of the transmitter device has nodes 112 corresponding to the channel input vector Xⁿ and the sequences of source symbols S^{m} are mapped directly to a representation as the channel input vector Xⁿ.

Information source 312 is input into input layer 102 of the first encoder neural network 212. Information source 322 is input into input layer 102 of the second encoder neural network 222. Information source 312 and information source 322 are examples of information source 302 of FIG. 3. Information source 312 is not the same as information source 322. For example, information source 312 may have a different structure to information source 322. In an example, the information source 312 received at the input to the first encoder neural network 212 may be of a different size to information source 322 received at the input to the second encoder neural network 222. In another example, information source 312 may be of a different type to information source 322. For example, information source 312 may be an image and information source 322 may be a video.

The joint source channel coding autoencoder 200 comprising the first encoder neural network 212 and the joint source channel coding autoencoder 200 comprising the second encoder neural network 222 are separate joint source channel coding autoencoders 200. In an example, the joint source channel coding autoencoder 200 comprising the first encoder neural network 212 and the joint source channel coding autoencoder 200 comprising the second encoder neural network 222 are different. As described above, the information source or type of information source input into the first encoder neural network is different to the information source or type of information source input into the second encoder neural network. The joint source channel coding autoencoder comprising the first encoder neural network 212 is trained for information source 312 and the joint source channel coding autoencoder comprising the second encoder neural network 222 is trained for information source 322. Thus, the joint source channel coding autoencoder 200 comprising the first encoder neural network 212 and the joint source channel coding autoencoder 200 comprising the second encoder neural network 222 are trained for different information sources. This means the neural network of the first encoder neural network 212 may differ to the neural network of the second encoder neural network 222. For example, the joint source channel coding autoencoder 200 comprising the first encoder neural network 212 and the joint source channel coding autoencoder 200 comprising the second encoder neural network 222 may have different amounts of neural network layers, different amounts of nodes per layer, different weights and/or biases associated with the nodes etc. Moreover, the first encoder neural network 212 and the second encoder neural network 222 may have different amounts of neural network layers, different amounts of nodes per layer, different weights and/or biases associated with the nodes etc.

FIG. 6 provides an illustration of a receiver device 600 according to an example. The receiver device 600 may comprise a first decoder neural network 214 and a second decoder neural network 224. Although two decoder neural networks are illustrated, the receiver device 600 may comprise any number of decoder neural networks that correspond to one of the plurality of encoder neural networks of the transmitter device. The receiver device 600 may be in communication with the transmitter device 500 of FIG. 5. The decoder neural networks 214, 224 of the receiver device may correspond to the encoder neural networks 212, 222 of the transmitter device. For example, a joint source channel coding autoencoder 200 may comprise first encoder neural network 212 and first decoder neural network 214 and a separate joint source channel coding autoencoder 200 may comprise second encoder neural network 222 and second decoder neural network 224. Thus, the communication channel between each encoder neural networks and corresponding decoder neural network may have the same characteristics and distribution. The number of decoder neural networks may equate to the number of encoder neural networks of the transmitter device 500.

In an alternative embodiment, first decoder neural network 214 and second decoder neural network 224 may be located in separate receiver devices. Thus, the communication channel of the first encoder neural network and the second encoder neural network may have different characteristics and distributions. Each receiver device may only have one decoder neural network. Transmitter device 500 may be in communication with both receiver devices. Each receiver device may comprise at least one decoder neural network corresponding to one of the plurality of encoder neural networks 212, 222 of the transmitter device 500.

Each decoder neural network 214, 224 of receiver device 200 may have a channel output layer having nodes corresponding to a channel output vector Yⁿ received from a receiver receiving a signal corresponding to at least the plurality of signal values X^{p} of the channel input vector Xⁿ transmitted by the transmitter and transformed by the communications channel, and an output layer coupled to the channel output layer through one or more neural network layers, having nodes matching those of the input layer of the encoder neural network, wherein the first decoder neural network is configured through training to map the representation of the source symbols as the channel output vector Yⁿ transformed by the communications channel to a reconstruction of the source symbols Ŝ^{m} output from the output layer of the joint source channel coding autoencoder, the reconstruction of the source symbols Ŝ^{m} being usable to reconstitute the information source.

The receiver device 600 also comprises a receiver 602 to receive a signal corresponding to the channel input vector Xⁿ transmitted by the transmitter of the transmitter device over the communications channel.

As encoder neural network is for a different information source or type of information source, the transmitter comprising the encoder neural networks is highly efficient for the specific information sources and is flexible in that it is capable of receiving a plurality of different information sources or types of information source

### Multiple Decoder Neural Networks of a Joint Source Channel Coding Autoencoder for Adaptive Bandwidth Expansion

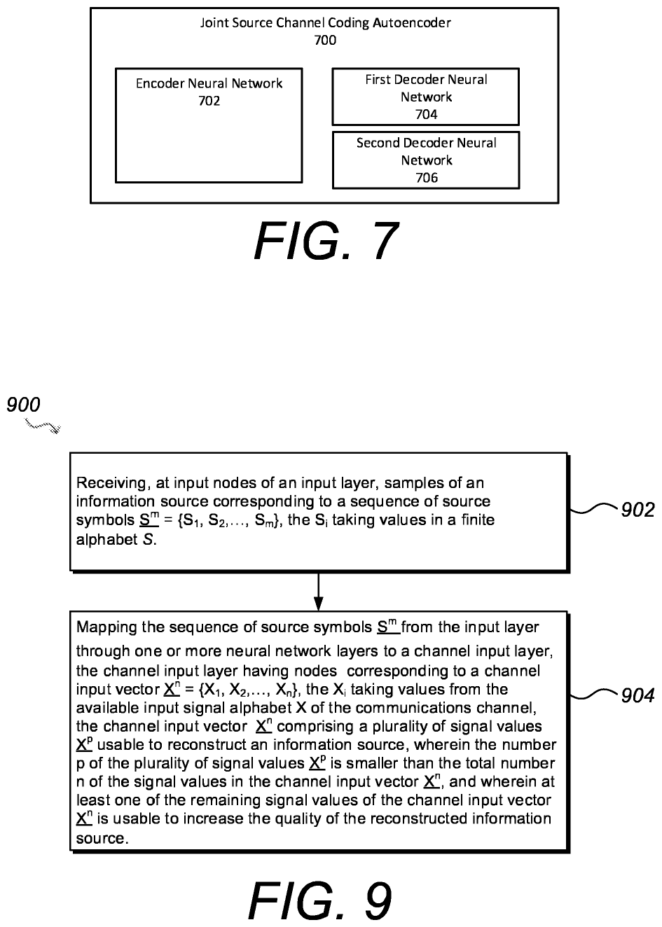

FIG. 7 provides another example of a joint source channel coding autoencoder. Joint source channel coding autoencoder 700 is an example of joint source channel coding autoencoder 200 of FIG. 2. As described in relation to FIG. 2, the neural network of FIG. 1 may also be a joint source channel coding autoencoder 700. Joint source channel coding autoencoder 700 comprises an encoder neural network 702, a first decoder neural network 704 and a second decoder neural network 706. Although two decoder neural networks are illustrated, the joint source channel coding autoencoder 700 may comprise any number of decoder neural networks 704, 706. Decoder neural network 704 and decoder neural network 706 of joint source channel coding autoencoder 700 are examples of decoder neural network 204.

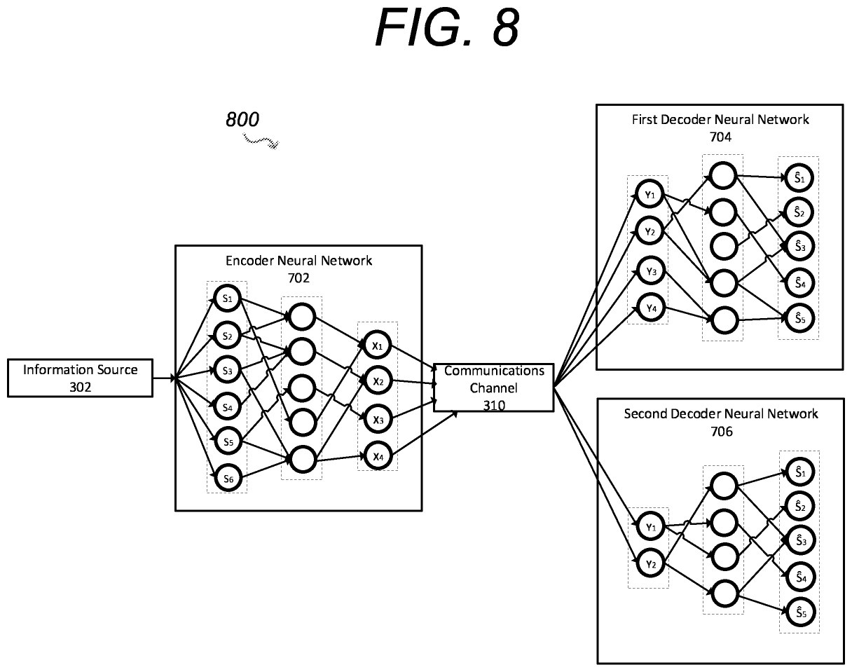

FIG. 8 provides an illustration of a communication system 800 according to another example. The communication system 800 is for conveying information from an information source across a communications channel using a joint source channel coding autoencoder such as joint source channel coding autoencoder 700 of FIG. 7. The communication system 800 comprises an encoder neural network 702, a first decoder neural network 704 and a second decoder neural network 706 of joint source channel coding autoencoder 700. Communication system 800 may comprise any number of encoder neural networks and decoder neural networks. For example, communication system 800 may comprise a plurality of decoder neural networks and may comprise one or more receiver devices comprising one or more of the plurality of decoder neural networks 704, 706. Encoder neural network 702 is an example of encoder neural network 202 of FIGS. 1 and 2 and decoder neural networks 704, 706 are examples of decoder neural network 204 of FIGS. 1 and 2. The first decoder neural network 704 and the second decoder neural network 706 are of the same joint source channel coding autoencoder 700 as the encoder neural network 702.

The encoder neural network 702 of the communication system 800 has an input layer 102 having input nodes corresponding to a sequence of source symbols S^{m}={S₁, S₂, . . . , Sₘ}, the Sᵢ taking values in an alphabet S, received at the input layer from the information source as samples thereof. The encoder neural network 702 also has a channel input layer 110 coupled to the input layer through one or more neural network layers, the channel input layer having nodes usable to provide values for the Xᵢ of a channel input vector Xⁿ={X₁, X₂, . . . , Xₙ}, the Xᵢ taking values from the available input signal alphabet X of the communications channel, the channel input vector Xⁿ comprising a plurality of signal values X^{p} usable to reconstruct an information source, wherein the number of the plurality of signal values X^{p} is smaller than the total number of signal values Xⁿ, and wherein at least one of the remaining signal values of the channel input vector Xⁿ is usable to increase the quality of the reconstructed information source. The encoder neural network 702 is configured through training to be usable to map sequences of source symbols S^{m} received from the information source directly to a representation as a channel input vector Xⁿ, usable to drive a transmitter to transmit a corresponding signal over the communications channel. In an example, the sequences of source symbols S^{m} received from the information source are mapped directly to a representation as a channel input vector Xⁿ.

The communication system 800 further comprises a first decoder neural network 704 and a second decoder neural network 706 of the joint source channel coding autoencoder 700. Each decoder neural network 704, 706 has a channel output layer 114 having nodes 116 corresponding to a channel output vector Y received from a receiver receiving a signal corresponding to at least the plurality of signal values X^{p} of the channel input vector Xⁿ transmitted by the transmitter and transformed by the communications channel 310, and an output layer 122 coupled to the channel output layer 114 through one or more neural network layers 118, having nodes matching those of the input layer 102 of the encoder neural network 702, wherein the decoder neural network is configured through training to map the representation of the source symbols as the channel output vector Y transformed by the communications channel 310 to a reconstruction of the source symbols Ŝ^{m} output from the output layer 122 of the joint source channel coding autoencoder 700, the reconstruction of the source symbols Ŝ^{m} being usable to reconstitute the information source 302. The number of signal values of the channel output vector Y received by the first decoder network 704 is more than the number of signal values of the channel output vector Y received by the second decoder neural network 706.

The plurality of signal values X^{p} may be a subset of the channel input vector Xⁿ. The channel output vector Y^{p} received from the receiver may correspond to a subset of the channel input vector Xⁿ, the subset transmitted by the transmitter and transformed by the communications channel. In an example, the sequences of source symbols S^{m} received from the information source 302 are mapped directly to a representation as a channel input vector Xⁿ. In an example, the reconstruction of the source symbols Ŝ^{m} of the first decoder neural network 702 is of a higher quality than the reconstruction of the source symbols Ŝ^{m} of the second decoder neural network 704. The plurality of signal values X^{p} usable to reconstruct an information source may be a plurality of consecutive signal values of the channel input vector Xⁿ and may be a first plurality of consecutive signal values of the channel input vector Xⁿ. The channel output layer of the first decoder neural network 702 may receive channel output vector Y^{p} from a receiver receiving a signal corresponding to the plurality of signal values X^{p} of the channel input vector Xⁿ. The channel output layer of the second decoder neural network may receive a channel output vector Yⁿ from a receiver receiving a signal corresponding to the channel input vector Xⁿ.

In an example, the number of symbols of the reconstruction of the source symbols Ŝ^{m} of the first decoder neural network is different to the number of symbols of the reconstruction of the source symbols Ŝ^{m} of the second decoder neural network. The number p of the plurality of signal values X^{p} may be based on the characteristics of the communications channel and/or capabilities of the receiver comprising the second decoder neural network. The number of p of the plurality of signal values X^{p} may be such that the information source can be reconstructed at the second decoder neural network. The number n of the channel input vector Xⁿ may be based on the characteristics of the communications channel and/or capabilities of the receiver comprising the first decoder neural network. In an example, the first decoder neural network 704 may receive all signal values transmitted by the encoder neural network 702.

The encoder neural network 702 of the communication system 800 may be included in a transmitter device such as the transmitter device of FIG. 4. The transmitter device is for conveying information from an information source across a communications channel using a joint source channel coding autoencoder 700. The first decoder neural network 704 and/or second decoder neural network 706 of FIG. 7 may be included in a receiver device such as the receiver device of FIG. 6. In an example, first decoder neural network 704 and second decoder neural network 706 may be located in the same receiver device, which is in communication with transmitter device. The receiver 602 of the receiver device may receive channel input vector Xⁿ, which may be input into the first decoder neural network 704 and the second decoder neural network may receive some of the signal values of the channel input vector Xⁿ such as the plurality of signal values X^{p}. The first decoder neural network 704 may therefore produce a higher quality reconstruction of the information source 302 than the second neural network 706 but the second decoder neural network 706 may be able to produce a reconstruction of the information source quicker than the first decoder neural network 704 due to having to receive and process fewer signal values.

Further, where only the reduced number of signal values X^{p} are transmitted/received over the communications channel (for example, when insufficient channel capacity/radio resources are allocated to allow the transmission of the entirety of the channel input vector Xⁿ), the second decoder neural network can still be used to reconstruct the information source, albeit with a lower quality. When the transmitter/receiver are able to transmit/receive an increased number of signal values such that the entirety of the channel input vector Xⁿ can be transmitted/received (for example, when increased channel capacity/radio resources are allocated), then the first decoder neural network can be used to reconstruct a higher quality version of the information source.

Alternatively, first decoder neural network 704 and second decoder neural network 706 may be located in separate receiver devices and the transmitter device may be in communication with both receiver devices. The receiver device comprising the first decoder neural network 704 may therefore produce a higher quality reconstruction of the information source 302 than the receiver device comprising the second neural network 706. However, the receiver device comprising the second decoder neural network 706 may be able to produce a reconstruction of the information source quicker than the receiver device comprising the first decoder neural network 704 due to having to receive and process fewer signal values.

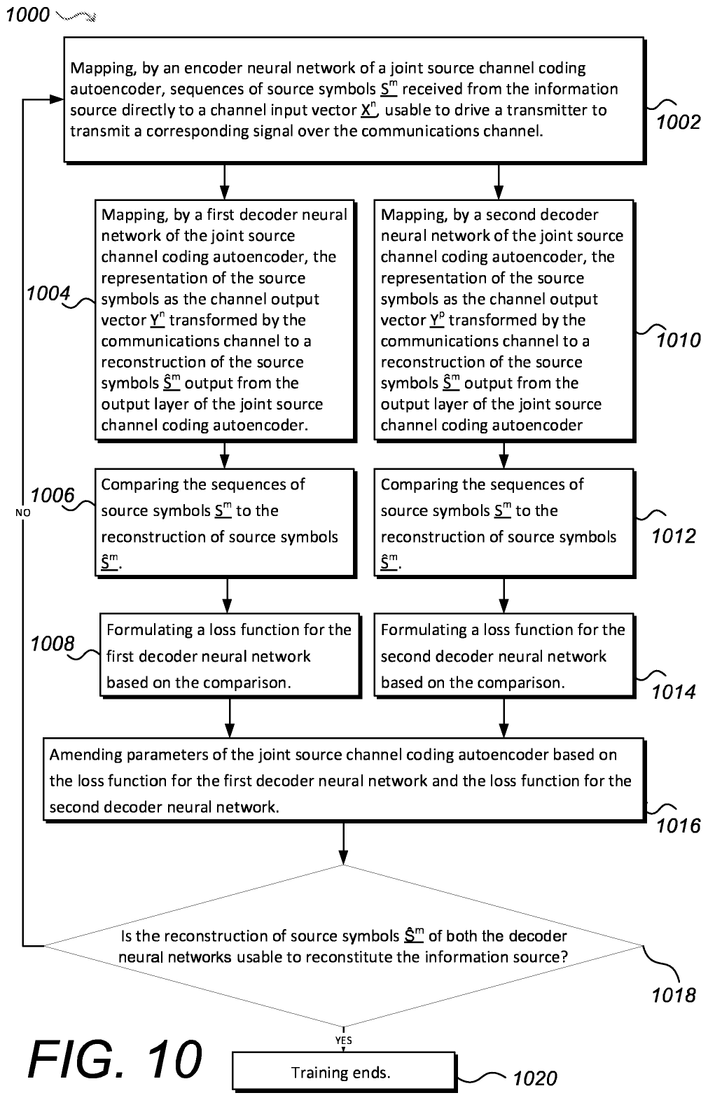

Depending on the locations of the separate receiver devices, the communication channel between the encoder neural network and the first decoder neural network and the communication channel between the encoder neural network and the second decoder neural network may have different characteristics and distributions. An advantage of the communication system is that the joint source channel coding autoencoder can be trained for one or more specific communication channels, even if they are different. The training method will be described later with reference to FIG. 10.

In an example, the second decoder neural network 706 may be located in a receiver device of a lower quality than the receiver device comprising the first decoder neural network 704. Hence, the second decoder neural network 706 may receive fewer signal values of each channel input vector Xⁿ than the first decoder neural network 704.

In an example, each of the remaining signal values of the channel input vector Xⁿ, when received in addition to the plurality of signal values X^{p}, are usable to produce a reconstruction of the source symbols Ŝ^{m} with a higher quality than the reconstruction of the source symbols Ŝ^{m} using the plurality of signal values X^{p}. For example, a receiver may receive only the plurality of signal values X^{p} of the channel input vector Xⁿ and the decoder neural network of the receiver reconstructs the information source. If the receiver also receives one remaining signal value, then the decoder neural network of the receiver can produce a reconstruction of the information source at a higher quality. If the receiver receives another remaining signal value, then the decoder neural network of the receiver can produce a reconstruction of the information source at a higher quality.

In another example, a plurality of the remaining signal values of the channel input vector Xⁿ, when received in addition to the plurality of signal values X^{p}, together are usable to produce a reconstruction of the source symbols Ŝ^{m} with a higher quality than the reconstruction of the source symbols Ŝ^{m} using the plurality of signal values X^{p}.

All of the remaining signal values of the channel input vector Xⁿ may be usable to increase the quality of the reconstructed information source. The first decoder neural network, the second decoder neural network and the encoder neural network may be trained jointly. The training method will be described later with reference to FIG. 10.

The encoder neural network 702 may be trained to produce a number of signal values to be transmitted to enable reconstruction and to produce additional signal values to be transmitted to enable reconstruction of a higher quality. In the example communication system 800 of FIG. 8, the total number of signal values transmitted at one time from the encoder neural network 802 may be four. Two signal values, Y_{1,2}, may be transmitted (for example when channel capacity/resource allocation only enables two signal values to be transmitted) to enable reconstruction of the information source to a reasonable level. The remaining signal values Y_{3,4}, when combined with the two signal values Y_{1,2}, can improve the quality of the reconstruction of the information source. Thus, if a receiver comprising a decoder neural network, such as the second decoder neural network 224, was to receive the two signal values Y_{1,2}, the decoder neural network 224 could reconstruct the information source. If a receiver comprising a decoder neural network, such as the first decoder neural network 704, was to receive the two signal values Y_{1,2} and both of the remaining signal values Y_{3,4}, receiving a total of four signal values, the first decoder neural network 704 could reconstruct the information source and the reconstruction would be of a higher quality than the reconstruction at both of the other receivers. This is an example of the communications system 800 but any number of signal values can be transmitted by the transmitter having the encoder neural network 202 and received from a receiver or receivers having the first decoder neural network 214 and/or second decoder neural network 224.

The quality of the reconstruction is determined by the similarity between the information source and the reconstruction of the information source. For example, if the reconstruction closely matches the information source, the reconstruction is of a high quality. Alternatively, if the reconstruction does not closely match the information source, the reconstruction is of a low quality. The quality of the reconstruction of the information source may be measured by the number of errors of the reconstruction or the number of symbols of the reconstruction. The measured number of errors may be a percentage of the total number of symbols of the reconstruction of the information source. The quality of the reconstruction of the information source may depend on the size of the information source and the size of the reconstruction of the information source.

FIG. 9 provides an example flowchart of a method 900 of an encoder neural network of a joint source channel coding autoencoder. The encoder neural network performing the method 900 may be encoder neural network 702 of FIGS. 7 and 8. The method 900 is for conveying information from an information source across a communications channel 310. Firstly, samples of an information source corresponding to a sequence of source symbols S^{m}={S₁, S₂, . . . , Sₘ}, the Sᵢ taking values in a finite alphabet S, are received 902 at input nodes of an input layer. Secondly, the sequence of source symbols S^{m} from the input layer are mapped 904 through one or more neural network layers to a channel input layer, the channel input layer having nodes usable to provide values for the Xᵢ of a channel input vector Xⁿ={X₁, X₂, . . . , Xₙ}, the Xᵢ taking values from the available input signal values of the communications channel 310. The channel input vector Xⁿ comprises a plurality of signal values X^{p} usable to reconstruct an information source. The number p of the plurality of signal values X^{p} is smaller than the total number n of the signal values in the channel input vector Xⁿ, and at least one of the remaining signal values

of the channel input vector Xⁿ is usable to increase the quality of the reconstructed information source. In this method 900, the encoder neural network 702 is configured through training to be usable to map sequences of source symbols S^{m} received from the information source directly to a representation as a channel input vector Xⁿ, usable to drive a transmitter to transmit a corresponding signal over a communications channel 310.

FIG. 10 is an example flowchart of a training method 1000 of a communication system 800. The training method 1000 is for training a joint source channel coding autoencoder 700 to convey information from an information source 302 across a communications channel 310. The training method 1000 is of a communication system 800 comprising an encoder neural network 702, a first decoder neural network 704 and a second decoder neural network 706, wherein the number of signal values of the channel output vector Y received by the first decoder network 704 is more than the number of signal values of the channel output vector Y received by the second decoder neural network 706. Firstly the encoder neural network 702 of the joint source channel coding autoencoder 700 maps 1002 sequences of source symbols S^{m} received from the information source to a representation as a channel input vector Xⁿ, usable to drive a transmitter to transmit a corresponding signal over the communications channel 310. Next, the first decoder network maps 1004 the representation of the source symbols as the channel output vector Y transformed by the communications channel to a reconstruction of the source symbols Ŝ^{m} output from the output layer of the joint source channel coding autoencoder 700. Following the mapping by the first decoder neural network, the sequences of source symbols S^{m} are compared 1006 to the reconstruction of source symbols Ŝ^{m} at the output layer of the first decoder neural network. A loss function is then formulated 1008 for the first decoder neural network 704 based on the comparison. The second decoder neural network 706 performs the same steps 1010, 1012, 1014 as the first decoder neural network 704. Once the loss functions of the first decoder neural network and second decoder network have been formulated, after both steps 1008 and 1014, parameters of the joint source channel coding autoencoder are amended 1016 based on the loss function for the first decoder neural network and the loss function for the second decoder neural network. It is then decided 1018 whether the reconstruction of source symbols Ŝ^{m} at the first decoder neural network is usable to reconstitute the information source and the reconstruction of source symbols Ŝ^{m} at the second decoder neural network is usable to reconstitute the information source. If both reconstructions are usable to reconstitute the information source, then the training ends 1020. If not, the steps 1002 to 1016 are repeated.

Steps 1004, 1006 and 1008 performed by the first decoder neural network 704 are independent of steps 1010, 1012 and 1014 performed by the second decoder neural network 706 and these sets of steps can therefore be performed independent of each other. For example, steps 1010, 1013 and 1014 can be performed in parallel, before or after steps 1004, 1006 and 1008. However, both steps 1004 and 1010 are performed after the mapping 1002 by the encoder neural network.

If the communication system 800 includes more than two decoder neural networks, steps 1004 to 1008 may be repeated for all of the decoder neural networks and the amending 1016 of the parameters will be based on the loss functions of all the decoder neural networks of the communication system 800. The steps 1002 to 1016 may be repeated until the reconstruction of source symbols Ŝ^{m} at the second decoder neural network is usable to reconstitute the information source and the reconstruction of source symbols Ŝ^{m} at the first decoder neural network is of a higher quality than the reconstruction of source symbols Ŝ^{m} at the second decoder neural network.

It is to be noted that the parameters of the joint source channel coding autoencoder 200 are only amended if the comparison shows that the reconstructions of source symbols Ŝ^{m} of the decoder neural networks are not usable to reconstitute the information source and/or are not at the required quality. In an example, sequences of source symbols S^{m} received from the information source are mapped directly to a representation as a channel input vector Xⁿ.

The parameters to be amended 1016 based on the comparison may be the weights and/or biases of the nodes of the neural network layers. The parameters may be amended 1016 based on the channel characteristics, for example signal to noise ratio. The communication system is flexible and so the encoder neural network could then also be used with differing channels with the same SNR. The channel characteristics may be found by using channel sounding, i.e. sending known pulses across the channel. The parameters may also be amended 1016 based on the information source, for example, based on the data structure of the information source. Through training, the neural network may increase in dimension to more than two dimensions.

As mentioned previously, the first decoder neural network 704 and the second decoder neural network 706 may be located in different receivers and so the communication channel between the encoder neural network 702 and the first decoder neural network 704 and the communication channel between the encoder neural network 702 and the second decoder neural network 706 may have different characteristics and distributions. During training, the parameters of the joint source channel coding autoencoder are amended to ensure that the reconstruction of source symbols Ŝ^{m} of both the decoder neural networks is usable to reconstitute the information source. Thus, the characteristics of the communication channel between the encoder neural network 702 and the first decoder neural network 704 and the characteristics of the communication channel between the encoder neural network 702 and the second decoder neural network 706 are learnt through training such that, for each decoder neural network, the channel output vector Yⁿ transformed by the communication channel can still be mapped to a reconstruction of source symbols Ŝ^{m} that is usable to reconstitute the information source.

As illustrated in FIG. 10, both decoder neural networks 704, 706 are trained jointly together with the encoder neural network 702. The decoder neural networks 704, 706 receive different amounts of signal values and the reconstruction of source symbols Ŝ^{m} may therefore differ. For example, as the first decoder neural network receives a larger number of signal values from the encoder neural network, the reconstruction of source symbols Ŝ^{m} at the first decoder neural network may be of a higher quality. The loss function indicates the quality of the reconstruction of source symbols Ŝ^{m} at each decoder neural network 704, 706. For example, the loss function of each decoder neural network is formulated based on the comparison of the sequences of source symbols Ŝ^{m} and the reconstruction of source symbols Ŝ^{m} at the output of the decoder neural network. Once the loss functions have been calculated, they may be weighted based on the desired quality of reconstruction at each receiver. For example, the parameters may be amended 1016 based on a loss function of the joint source channel coding autoencoder. This loss function may be a weighted sum of the loss functions for each decoder neural network. The weighting of the loss functions may be amended to balance the reconstruction qualities of the first decoder neural network and the second decoder neural network. For example, weighting of each of the loss functions is based on the quality of the communications channel between the encoder neural network and the first decoder neural network and the quality of the communications channel between the encoder neural network and the second decoder neural network. In an example, the weighting of each of the loss functions is based on the desired reconstruction quality of the first decoder neural network and the second decoder neural network.

The quality of the reconstruction of the second decoder neural network 706 may be higher as it has received more information. However, the weighting factor will determine how much emphasis is put on the quality of each layer. For example, putting all the weight on one of the decoders will ignore the other, and hence, the ignored network will not be trained, whereas in general, the autoencoder will learn to balance the reconstruction qualities of the two decoders.

In summary, there is provided a transmitter device 500 for conveying information from an information source 302 across a communications channel 310 using a joint source channel coding autoencoder 200, comprising: a plurality of encoder neural networks 202, each encoder neural network 202 of a joint source channel coding autoencoder 200, and each encoder neural network 202 trained to receive a different information source 302 or a different type of information source 302, wherein each encoder neural network 302 comprises: an input layer 102 having input nodes 104 corresponding to a sequence of source symbols S^{m}={S₁, S₂, . . . , Sₘ}, the Sᵢ taking values in a finite alphabet S, received at the input layer from an information source 302 as samples thereof, and a channel input layer 110 coupled to the input layer 102 through one or more neural network layers 106, the channel input layer 110 having nodes 112 usable to provide values for the Xᵢ of a channel input vector Xⁿ={X₁, X₂, . . . , Xₙ}, the Xᵢ taking values from the available input signal alphabet X of the communications channel 310, wherein the encoder neural network 202 is configured through training to be usable to map sequences of source symbols S^{m} received from the information source 302 directly to a representation as a channel input vector Xⁿ, usable to drive a transmitter 404 to transmit a corresponding signal over a communications channel 310; and a transmitter 404 to transmit the channel input vector Xⁿ over the communications channel 310.

Moreover, there is provided a communication system 800 for conveying information from an information source 302 across a communications channel 310 using a joint source channel coding autoencoder 700, comprising: an encoder neural network 702 of the joint source channel coding autoencoder 700, the encoder neural network 702 having: an input layer 102 having input nodes 104 corresponding to a sequence of source symbols S^{m}={S₁, S₂, . . . , Sₘ}, the Sᵢ taking values in an alphabet S, received at the input layer 102 from the information source 302 as samples thereof, and a channel input layer 110 coupled to the input layer 102 through one or more neural network layers 106, the channel input layer 110 having nodes 112 usable to provide values for the Xᵢ of a channel input vector Xⁿ={X₁, X₂, . . . , Xₙ}, the Xᵢ taking values from the available input signal alphabet X of the communications channel 310, the channel input vector Xⁿ comprising a plurality of signal values X^{p} usable to reconstruct an information source 302, wherein the number p of the plurality of signal values X^{p} is smaller than the total number n of signal values of the channel input vector Xⁿ, and wherein at least one of the remaining symbols of the channel input vector Xⁿ is usable to increase the quality of the reconstructed information source. The encoder neural network 702 is configured through training to be usable to map sequences of source symbols S^{m} received from the information source 302 directly to a representation as a channel input vector Xⁿ, usable to drive a transmitter to transmit a corresponding signal over the communications channel 310; a first decoder neural network 704 and a second decoder neural network 706 of the joint source channel coding autoencoder 700, each decoder neural network having: a channel output layer 114 having nodes corresponding to a channel output vector Y received from a receiver receiving a signal corresponding to at least the plurality of signal values X^{p} of the channel input vector Xⁿ transmitted by the transmitter and transformed by the communications channel 310, and an output layer 122 coupled to the channel output layer through one or more neural network layers 118, having nodes matching those of the input layer 102 of the encoder neural network 702, wherein the decoder neural network is configured through training to map the representation of the source symbols as the channel output vector Y transformed by the communications channel 310 to a reconstruction of the source symbols Ŝ^{m} output from the output layer 122 of the joint source channel coding autoencoder 700, the reconstruction of the source symbols Ŝ^{m} being usable to reconstitute the information source 302; and wherein the number of signal values of the channel output vector Y received by the first decoder network 704 is more than the number of signal values of the channel output vector Y received by the second decoder neural network 706.

The plurality of decoder neural networks of the joint source channel coding autoencoder connected to the encoder neural network of the joint source channel coding autoencoder enable a flexible system whereby the encoder neural network can transmit a channel input vector Xⁿ that enables both decoder neural networks to reconstruct the information source even if they receive a differing ‘amount’ of the signal corresponding to the channel input vector Xⁿ. The plurality of decoder neural networks in the joint source channel coding autoencoder enable multiple levels of reconstruction at one receiver or reconstruction at all receivers, if the decoder neural networks are located in separate receivers, even if the receivers have different capabilities. Also, the joint source channel coding can be responsive to changes in channel capacity/resource allocation on the communications channel, allowing sufficient symbols to be communicated to allow reconstruction of a relatively low quality version of the information source at times of relatively low channel capacity, and sufficient symbols to be communicated to allow reconstruction of a relatively high quality version of the information source at times of relatively high channel capacity.

### Joint Source Channel Coding Variational Autoencoder

A variational autoencoder is a particular type of autoencoder. Thus, the joint source channel coding variational autoencoder is an example of the joint source channel coding autoencoders detailed above, such as joint source channel coding autoencoders 200 of FIG. 2 and 700 of FIG. 7. Joint source channel coding variational autoencoders have the same advantages as joint source channel coding autoencoders. Moreover, the features of the joint source channel coding autoencoder, as previously explained, also apply to the joint source channel coding variational autoencoder. Thus, features of the joint source channel coding autoencoder may also be features of the joint source channel coding variational autoencoder and features of the joint source channel coding variational autoencoder may also be features of the joint source channel coding autoencoder.

In an autoencoder, the goal of the system is to make sure that each input can be regenerated based on the encoder output. The encoder therefore tries to learn the most essential features of each input data sample. But, for example, if the encoder output dimension is sufficiently large, each input data point could be mapped to a distinct output, and the decoder can simply learn the inverse mapping from encoder outputs to input values. In principle, the encoder can map two similar inputs to completely different output values. Therefore, in an autoencoder, if the encoder output differs from the decoder input (for example due to a noisy channel), the decoder neural network may not be able to reconstruct the information source. This is because the output layer of the encoder neural network comprises specific values. Even if the values are similar, these similar values may map to other specific values that may be very different. A variational autoencoder enables optimisation of the reconstruction of the information source. For a variational autoencoder, the goal is to learn the stochastic model that generates the underlying source signals. Therefore, in a variational autoencoder, the outputs of the encoder neural network are parameters of distributions, the distributions being based on certain features of the input data and being randomly sampleable to provide output values. The sampler may be considered to form part of the variational autoencoder.

For example, the distributions may be based on statistical features of a structured data set. In another example, the distributions may be based on features of an image, such as a face, or a smile. In another example, the distributions may be based on abstract structures that generate the image. If the (sampled) output of the encoder neural network differs from the input to the decoder neural network (for example due to a noisy channel), the variational autoencoder can still produce a reconstruction of the information source, which decreases in quality as the difference between encoder neural network output a decoder neural network input increases. The variational autoencoder will be explained further in the following figures.

The variational autoencoder in accordance with examples of the present disclosure can be used in a communication system for conveying information from an information source across a communications channel. The encoder neural network of the variational autoencoder can replace the traditional source encoder and channel encoder. The encoder neural network maps the signal directly to the channel input layer (or to distributions therein defined by the encoder neural network), where it is sampled and transmitted over the communications channel. The decoder neural network of the variational autoencoder can replace the traditional source decoder and channel decoder. The decoder neural network receives the output of the communications channel and reconstructs the signal. The encoder neural network and decoder neural network are trained to undo the effect of the channel on the signal, such as the effect of the channel noise of the signal. The encoder neural network and decoder neural network can also be trained to learn a representation of the source signal and recover the input with the highest fidelity possible. Further, as the neural networks are trained to optimise the mapping, the efficiency of the transmission of the information source over the communications channel can be greater than in separate source and channel coding, where the separate removal and subsequent addition of redundancy may be inherently inefficient for transferring the data.

Thus, the encoder and decoder neural networks can be used as a form of joint source channel coding. This provides simplicity over having two separate systems for encoding and two separate systems for decoding. However, the limitations of the joint source channel coding techniques as mentioned above are removed. In particular, a variational autoencoder used for joint source channel coding, herein referred to as the joint source channel coding variational autoencoder, can be trained for use with different channels and different input sources. Thus, using neural networks for conveying information across a channel enables a high degree of freedom.

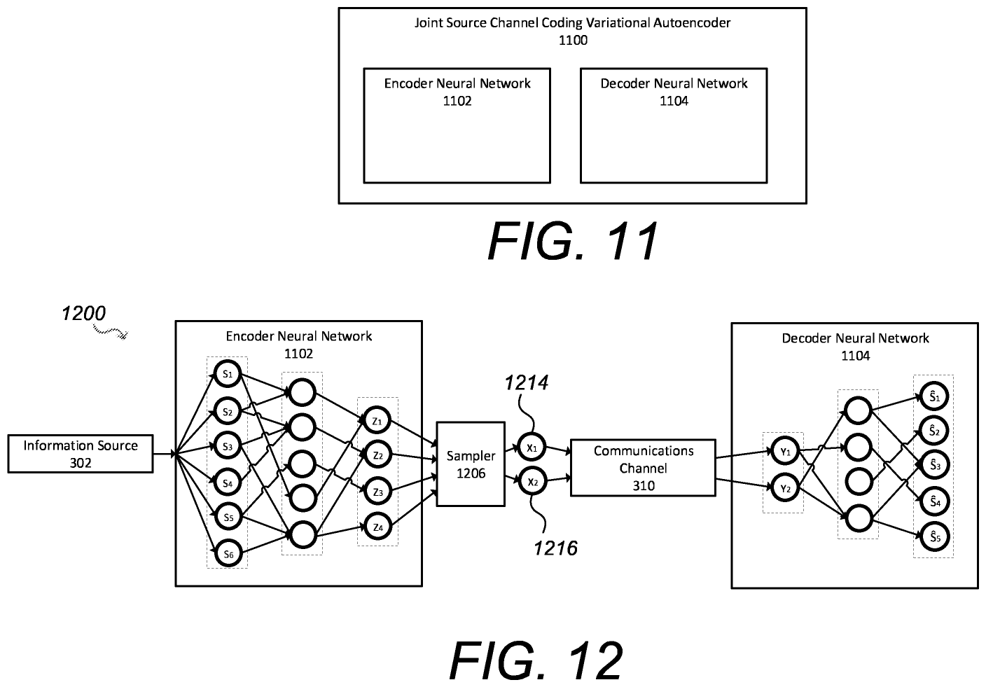

FIG. 11 provides an example of a joint source channel coding variational autoencoder 1100. The joint source channel coding variational autoencoder 1100 comprises an encoder neural network 1102 and a decoder neural network 1104. The encoder neural network and decoder neural network may be deep and/or recurrent.

For example, with reference to FIG. 1, the neural network of FIG. 1 may be a joint source channel coding variational autoencoder 1100. The encoder neural network 1102 of the joint source channel coding variational autoencoder 1100 may be formed from layers 102, 106 and 110. The decoder neural network 1104 of the joint source channel coding variational autoencoder 1100 may be formed from layers 114, 118 and 122.

With reference to FIGS. 1 and 11, the encoder neural network 1102 of the joint source channel coding variational autoencoder 1100 has an input layer 102 having input nodes 104 corresponding to a sequence of source symbols S^{m}={S₁, S₂, . . . , Sₘ}, the Sᵢ taking values in a finite alphabet S, received at the input layer 102 from an information source as samples thereof. The encoder neural network 1102 also has a channel input layer 110 coupled to the input layer through one or more neural network layers 106, the channel input layer 110 having nodes 112 corresponding to a channel input distribution vector Z^{k}={Z₁, Z₂, . . . , Z_{K}}, the Zᵢ taking values for parameters defining a plurality of distributions, each distribution being sampleable to provide possible values for the Xᵢ of a channel input vector Xⁿ={X₁, X₂, . . . , Xₙ}, the Xᵢ taking values from the available input signal values of a communications channel.

The encoder neural network 1102 is configured through training to map sequences of source symbols S^{m} received from the information source directly to a representation as a plurality of distributions that provide possible values for the Xᵢ of a channel input vector Xⁿ, usable to drive a transmitter to transmit a corresponding signal over the communications channel.

In an example, the channel input layer 110 is coupled to the input layer 102 through at least five neural network layers 106. The encoder neural network 1102 may directly map the input nodes 104 at the input layer 102, corresponding to a sequence of source symbols S^{m}, to the nodes 112 of the channel input layer 110, corresponding to a channel input distribution vector Z^{k}, through the neural network.

In the communication system, for a wireless communications channel in accordance with an example, each input signal Xᵢ of the channel input vector Xⁿ may belong to a set of complex numbers, corresponding to the I and Q components. In an example, the encoder neural network 1102 of the joint source channel coding variational autoencoder 1100 may perform bandwidth compression. For example, the encoder neural network 1102 may compress the information source during mapping such that the size n of the channel input vector Xⁿ is smaller than the size m of the source symbols S^{m}. Alternatively, the joint source channel coding variational autoencoder 1100 may perform a bandwidth expansion, where the size n of the channel input vector Xₙ is larger than the size m of the source symbols Sₘ.

In an example, the plurality of distributions have the same distribution type. For example, the plurality of distributions may be Gaussian distributions defined by a mean and a standard deviation. In an example, for k/2 Gaussian distributions, the first k/2 elements of the channel input distribution vector Z^{k} encode the mean value of the corresponding channel input distributions, while the remaining k/2 elements of the channel input distribution vector Z^{k} encode the standard deviations of the corresponding channel input distributions. In this example, the i-th channel input Xᵢ is a sample from a Gaussian distribution with mean Zᵢ and standard deviation Zᵢ₊ₖ. In an example, each distribution of the plurality of distributions is sampled once. Thus, for distributions defined by two distribution parameters, the size n of the channel input vector Xⁿ is half the size k of the channel input distribution vector Z^{k}. Moreover, in such an example, the channel input vector Xⁿ comprises one sample from each distribution of the plurality of distributions.

The distribution type of the plurality of distributions may be the optimal input distribution for the channel. Thus, by understanding channel models, the optimal input distributions can be calculated. The encoder neural network 1102 may be trained as part of the training of the joint source channel coding variational autoencoder 1100 to learn the parameters of the plurality of distributions. In an example, the type of distribution of the plurality of distributions is based on the characteristics of the communication channel. For example, the type of distribution may be based on the distribution model of the channel noise or the fading. For example if the communications channel can be modelled as a Gaussian channel, then the plurality of distributions are Gaussian distributions.

An advantage of using a variational autoencoder for conveying information over a communications channel is that, for many common channel models such as binary symmetric channels and AWGN channels, we know the optimal input distribution. Moreover, when transmitting a Gaussian source distribution over a Gaussian channel, no coding is necessary, and simple uncoded transmission with power allocation achieves the optimal Shannon bound. Thus, if the channel is AWGN, by using the joint source channel coding variational autoencoder 1100, the channel can be used at its theoretical limit. This suggests that if we can represent the underlying data set through a Gaussian distribution, as is achievable in examples of the present disclosure, that would correspond to the optimal input distribution to the channel.

When the neural network of FIG. 1 is modelled as a joint source channel coding variational autoencoder, channel input layer 110 and channel output layer 114 are not directly connected, as indicated by the dashed arrows connecting the nodes of these layers. The communications channel is between channel input layer 110 and channel output layer 114. Thus, the values output from the (sampled distributions defined by the) encoder neural network may not be equal to the values input into the decoder neural network.

The decoder neural network 1104 is to map the channel output sequence to a reconstructed version of the channel input vector Ŝ^{m}. The decoder neural network 1104 may be a standard decoder of an autoencoder. The mapping may be a deterministic mapping. Alternatively the mapping may be a probabilistic mapping.

The decoder neural network 1104 of the joint source channel coding variational autoencoder 1100 has a channel output layer 114 having nodes 116 corresponding to a channel output vector Yⁿ received from a receiver receiving the signal Xⁿ transmitted by the transmitter and transformed by the communications channel. The decoder neural network 1104 also has an output layer 122 coupled to the channel output layer 114 through one or more neural network layers 118, having nodes 124 matching those of the input layer 104 of the encoder neural network.

The decoder neural network 1104 is configured through training to map the representation of the source symbols as the channel output vector Yⁿ transformed by the communications channel to a reconstruction of the source symbols Ŝ^{m} output from the output layer of the joint source channel coding variational autoencoder 1100, the reconstruction of the source symbols Ŝ^{m} being usable to reconstitute the information source.

In an example, the channel output layer 114 is coupled to the output layer 122 through at least five neural network layers 118. The decoder neural network 1104 may directly map the nodes 116 at the channel output layer 114, corresponding to a channel output vector Yⁿ, to the nodes 124 of the output layer 122, corresponding to a reconstruction of the source symbols Ŝ^{m}, through the neural network.

The encoder neural network 1102 and decoder neural network 1104 may have any number of layers and each layer may comprise any number of nodes. In an example, the output layer of the encoder neural network 1102 has the same number of nodes as the input layer of the decoder neural network 1104. In another example, the input layer of the encoder neural network 1102 has the same number of nodes as the output layer of the decoder neural network 1104.

In an example, the size n of the channel input vector Xⁿ is based on the channel capacity or the channel resources allocated for use by the transmitter (for example, the radio resources, or OFDM symbols, allocated to a radio bearer for a transmitter terminal for digital (e.g. QAM) modulation thereby in an LTE communication system). Alternatively or additionally, the size n of the channel input vector Xⁿ may be based on the size m of the source symbols S^{m} or the size m of the reconstruction of the source symbols Ŝ^{m}. In an example, the size of the source symbols S^{m} is not equal to the size of the reconstruction of the source symbols Ŝ^{m}. The size k of the channel input distribution vector Z^{k} may be larger than the size n of the channel input vector Xⁿ. The size m of the reconstruction of the source symbols Ŝ^{m} may be larger than the size n of the channel output vector Yⁿ. The size n of the channel input vector Xⁿ may be equal to the size n of the channel output vector Yⁿ In another example, the size n of the channel input vector Xⁿ may be different from the size n of the channel output vector Yⁿ, for example, for a multiple input multiple output channel.

FIG. 12 provides an illustration of a communication system 1200 according to an example. The communication system comprises an information source 302. The information source 302 has been described previously with reference to FIG. 3. The information source is input into input layer 102 of the encoder neural network 1102 of the joint source channel coding variational autoencoder 1100. The encoder neural network 1102 is described above with reference to FIGS. 1 and 11. The encoder neural network 1102 has a channel input layer 110 coupled to the input layer 102 through one or more neural network layers 106, the channel input layer 110 having nodes 112 corresponding to a channel input distribution vector Z^{K}={Z₁, Z₂, . . . , Z_{K}}, the Zᵢ taking values for parameters defining a plurality of distributions.

The communication system 1200 further comprises a sampler 1206. The sampler 306 receives the channel input distribution vector Z^{k}={Z₁, Z₂, . . . , Z_{K}} and samples the respective distribution for each channel input Xᵢ defined by the channel input distribution vector to produce a channel input vector Xⁿ={X₁, X₂, . . . , Xₙ}. For example, the sampler may produce outputs X₁ 1214 and X₂ 1216. The sampler will be described in more detail below. The sample values may need to be normalized before being input into the communications channel to comply with average input power constraints.

Channel input vector Xⁿ may be transmitted across communications channel 310. Communications channel has been described previously with reference to FIG. 3. Due to the use of distributions, even if the input to the decoder neural network 1104 does not equal the output of the encoder neural network 1102, the joint source channel coding variational autoencoder 1100 may still be able to reconstruct the information source 302. This is because the channel input distribution vector defines a plurality of distributions, each distribution being sampleable to provide possible values for the Xᵢ of a channel input vector usable to drive a transmitter to transmit a corresponding signal over the communications channel 310. As described above, the plurality of distributions enable graceful degradation of the performance of the communications system. This means that the quality of reconstruction of the input source slowly degrades as the channel noise increases.

As the input to the decoder neural network becomes less similar to the output of the encoder neural network, the reconstruction of the information source reduces in similarity to the information source and consequently the quality of the reconstruction is reduced. In this example, as the noise of the communications channel 310 increases, the difference between the sequence of source symbols S^{m} and the reconstruction of the source symbols Ŝ^{m} may increase.

The decoder neural network 1104 receives the channel output vector. The decoder neural network 1104 is described above with reference to FIGS. 1 and 11. Thus the decoder neural network of the communication system produces a reconstruction of the source symbols Ŝ^{m} usable to reconstitute the information source 302.

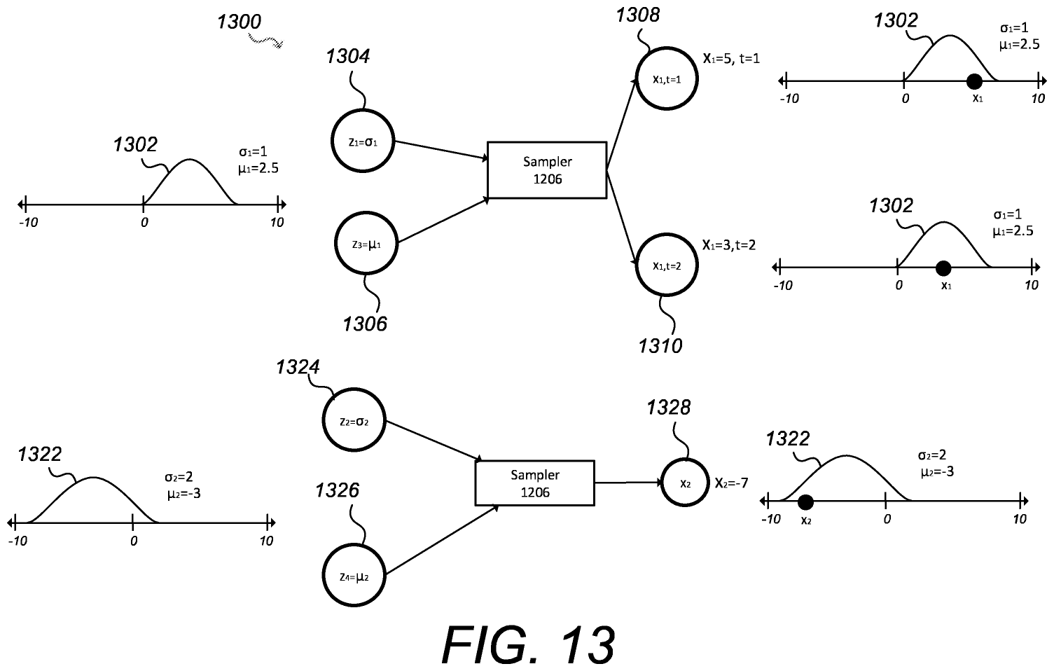

FIG. 13 provides an illustration of the sampler 1206 according to an example. Sampler 1206 may receive two inputs Z₂ 1324 and Z₄ 1326. These inputs are the parameters of a distribution such as distribution 1322. Sampler 1206 may sample the distribution defined by the parameters Z₂ and Z₄ to produce an output X₂ 1328. The output X₂ 1328 may be any value that falls within the distribution 1322 and is illustrated by the spot labelled X₂ on the scale.

In an example, the distribution 1322 is a Gaussian distribution with a mean and a standard deviation. For example, the Gaussian distribution may have a standard deviation σ₂=2 and a mean μ₂=−3. Z₂ 1324 provides the standard deviation and Z₄ 1326 provides the mean to the sampler. The sampler samples the Gaussian distribution to produce the output X₂ 1328. For example, when sampling a Gaussian distribution with a standard deviation σ₂=2 and a mean μ₂=−3, the sampler may produce output X₂=−7.

In another example, sampler 1206 may receive two inputs Z₁ 1304 and Z₃ 1306. These inputs are the parameters of a distribution such as distribution 1302. Sampler 1206 may sample the distribution defined by the parameters Z₁ and Z₃ to produce an output X₁ 1308, 1310. The output X₁ 1308, 1310 may be any value that falls within the distribution 1302 and is illustrated by the spots labelled output X₁ on the scale.

In an example, the distribution 1302 is a Gaussian distribution with a mean and a standard deviation. For example, the Gaussian distribution 1302 may have a standard deviation σ₁=1 and a mean μ₁=2.5. Z₁ 1304 provides the standard deviation and Z₃ 1306 provides the mean to the sampler. The sampler randomly samples the distribution 1302. Therefore, the output of the sampler varies even if the same input distribution is used. It is acknowledged that the distribution and, consequently, the parameters of the distribution will not be constant but will vary depending on the information source. Nevertheless, for illustrational purposes, at a first time and a second time the sampler receives the same parameters. For example, at a first time, t=1, the sampler may receive parameters defining the distribution 1302 and samples the distribution 1302 to produce the output X₁=5. At a second time, the sampler may receive parameters defining the distribution 1302 and produce the output X₁=3. Thus, an input of the encoder neural network does not directly map to a specific output of the encoder neural network. Even if the values at the input layer remain constant, the output values will constantly change due to the sampling of the distribution. Thus, the input layer of the decoder neural network will receive differing values but will learn to map these back to the same information source in order to reconstruct the information source. Therefore, even if the output of the encoder neural network is distorted when transmitted through the channel, the decoder neural network will receive different values but will still be able to reconstruct the information source.

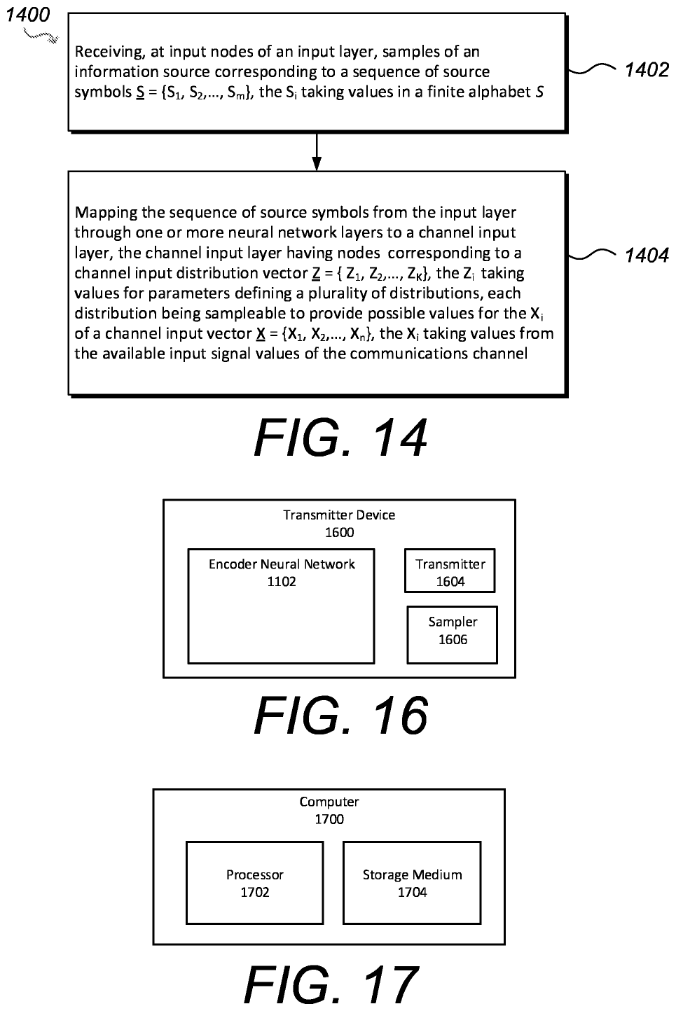

FIG. 14 provides an example flowchart of a method 1400 of an encoder neural network 1102 of a joint source channel coding variational autoencoder 1100. The method 1400 is for conveying information from an information source across a communications channel 310. Firstly, samples of an information source corresponding to a sequence of source symbols S^{m}={S₁, S₂, . . . , Sₘ}, the Sᵢ taking values in a finite alphabet S, are received 1402 at input nodes of an input layer. Secondly, the sequence of source symbols S^{m} from the input layer are mapped 1404 through one or more neural network layers to a channel input layer, the channel input layer having nodes corresponding to a channel input distribution vector Z^{k}={Z₁, Z₂, . . . , Z_{K}}, the Zᵢ taking values for parameters defining a plurality of distributions, each distribution being sampleable to provide possible values for the Xᵢ of a channel input vector Xⁿ={X₁, X₂, . . . , Xₙ}, the Xᵢ taking values from the available input signal values of the communications channel 310. In this method 1400, the encoder neural network 1102 is configured through training to map sequences of source symbols S^{m} received from the information source directly to a representation as a plurality of distributions that provide possible values for the Xᵢ of a channel input vector Xⁿ, usable to drive a transmitter to transmit a corresponding signal over a communications channel 310.

The encoder neural network 1102 and decoder neural network 1104 of the joint source channel coding variational autoencoder 1100 may be trained jointly to obtain a neural network capable of sufficiently reconstructing the information source 302. For example, they may be trained jointly based on the characteristics of the communication channel, based on the type of information source, for a given information source and/or to meet channel input constraints. The encoder neural network 1102 and decoder neural network 1104 of the joint source channel coding variational autoencoder 1100 may be trained jointly using performance measures. One performance measure may be the loss function.

The encoder neural network 1102 and decoder neural network 1104 of the joint source channel coding variational autoencoder 1100 may be trained jointly to minimise the difference between the input and output of the joint source channel coding variational autoencoder 1100. The difference between the input and output of the joint source channel coding variational autoencoder 1100 may be another performance measure. The difference may be measured by observing the similarity between the information source and the reconstructed information source. Alternatively or additionally, the difference may be measured by finding the “distance” between the actual channel input distribution and the target distribution. The distance between the probability distributions can be measured using KL divergence. For target distribution q(Xⁿ), the KL divergence D_{KL} is calculated using the following equation.

D_{KL}[P_{ϕ}(Xⁿ|S^{m})∥q(Xⁿ]

Where ϕ represents the encoder network parameters. For an AWGN channel, since a Gaussian input distribution is capacity-achieving, the target distribution may be set as a zero-mean Gaussian with covariance P·I, where P is the average input power constraint. Thus, the encoder neural network 1102 and decoder neural network 1104 may be trained jointly based on the measure of distance from the target distribution to the plurality of distributions.

Joint training has been further explained with reference to the encoder neural network 202 and decoder neural network 204 of the joint source channel coding autoencoder 200 of FIG. 2 and the same training can be applied to the joint source channel coding variational autoencoder 1100 of FIG. 11.

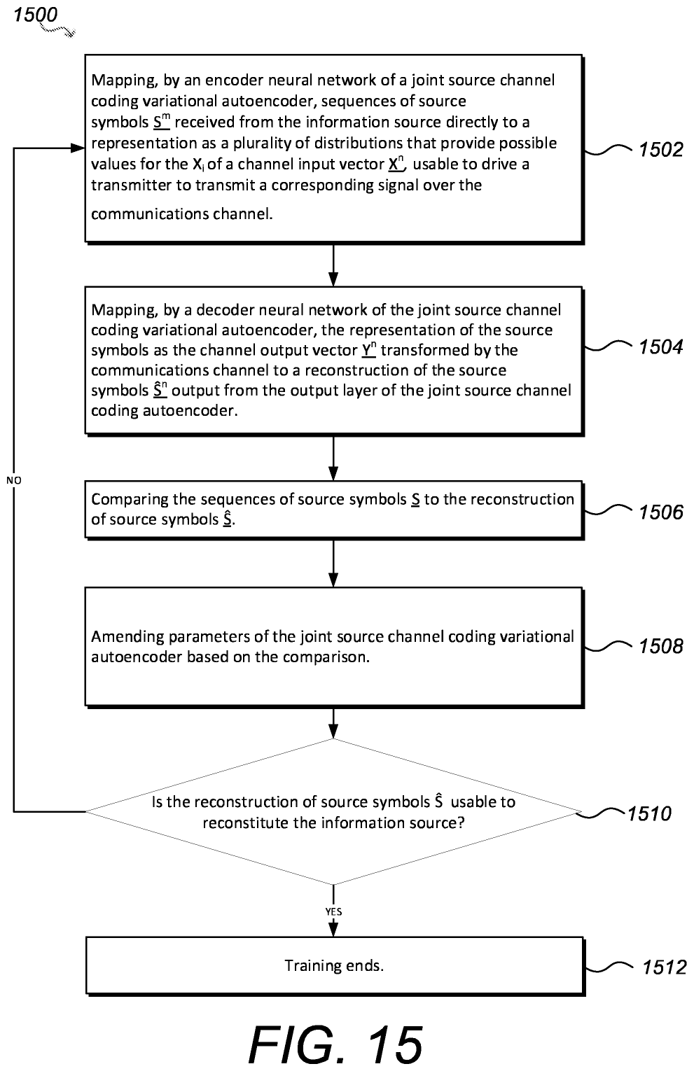

FIG. 15 provides an example flowchart of a training method 1500 of a communication system 1200. The training method 1500 is for training a joint source channel coding variational autoencoder 1100 to convey information from an information source 302 across a communications channel 310. Firstly the encoder neural network 1102 of the joint source channel coding variational autoencoder 1100 maps 1502 sequences of source symbols S^{m} received from the information source directly to a representation as a plurality of distributions that provide possible values for the Xᵢ of a channel input vector Xⁿ, usable to drive a transmitter to transmit a corresponding signal over the communications channel 310. Next, the decoder neural network 1104 of the joint source channel coding variational autoencoder 1100, maps 1504 the representation of the source symbols as the channel output vector Yⁿ transformed by the communications channel to a reconstruction of the source symbols Ŝ^{m} output from the output layer of the joint source channel coding variational autoencoder 1100. Following the mapping by the encoder neural network and decoder neural network, the sequences of source symbols S^{m} are compared 1506 to the reconstruction of source symbols Ŝ^{m}. The parameters of the joint source channel coding variational autoencoder 1100 are then amended 1508 based on the comparison. It is then decided 1510 whether the reconstruction of source symbols Ŝ^{m} is usable to reconstitute the information source. If the reconstruction of source symbols Ŝ^{m} is usable to reconstitute the information source, then the method ends 1512. If not, the method steps 1502 to 1508 are repeated until the reconstruction of source symbols Ŝ^{m} is usable to reconstitute the information source. It is to be noted that the parameters of the joint source channel coding variational autoencoder 1100 are only amended if the comparison shows that the reconstruction of source symbols Ŝ^{m} is not usable to reconstitute the information source.

The parameters to be amended 1508 based on the comparison may be the weights and/or biases of the nodes of the neural network layers. The parameters of the distributions may be trained based on the characteristics of the channel. For example, the channel capacity differs based on the signal to noise ratio (SNR) and so the encoder neural network can be trained based on the SNR. The communication system is flexible and so the encoder neural network can then also be used with differing channels with the same SNR. The channel characteristics may be found by using channel sounding, i.e. sending known pulses across the channel. The parameters of the distributions may be trained based on the information source, for example, based on the data structure of the information source. Through training, the neural network may increase in dimension to more than two dimensions.

FIG. 16 provides an example of a transmitter device 1600. The transmitter device 1600 comprises an encoder neural network 1102 of a joint source channel coding variational autoencoder 1100, a transmitter 1604 and a sampler 1606. The encoder neural network 1102 of the transmitter device 1600 comprises an input layer having input nodes corresponding to a sequence of source symbols S^{m}={S₁, S₂, . . . , Sₘ}, the Sᵢ taking values in a finite alphabet S, received at the input layer from an information source as samples thereof, and a channel input layer coupled to the input layer through one or more neural network layers, the channel input layer having nodes corresponding to a channel input distribution vector Z^{k}={Z₁, Z₂, . . . , Z_{K}}, the Zᵢ taking values for parameters defining a plurality of distributions, each distribution being sampleable to provide possible values for the Xᵢ of a channel input vector Xⁿ={X₁, X₂, . . . , Xₙ}, the Xᵢ taking values from the available input signal values of the communications channel, wherein the encoder neural network is configured through training to map sequences of source symbols S^{m} received from the information source directly to a representation as a plurality of distributions that provide possible values for the Xᵢ of a channel input vector Xⁿ, usable to drive a transmitter to transmit a corresponding signal over a communications channel.

The sampler 1606 of the transmitter device 1600 is configured to produce a channel input vector Xⁿ={X₁, X₂, . . . , Xₙ} in use by sampling the respective distribution for each channel input Xᵢ defined by the channel input distribution vector Z^{k}={Z₁, Z₂, . . . , Z_{K}} output by the channel input layer of the encoder neural network. The sampler may be an example of the sampler 1206 of FIG. 12. The transmitter 1604 of the transmitter device 1600 transmits the channel input vector Xⁿ over the communications channel.

FIG. 17 is a schematic diagram showing a computer 1700 according to an example. Computer 1700 comprises a processor 1702 and a storage medium 1704. The storage medium 1704 is a computer-readable storage medium comprising instructions which, when executed by the computer 1700, cause the computer 1700 to carry out the steps of method 900 of FIG. 9 or method 1000 of FIG. 10 or method 1400 of FIG. 14 or method 1500 of FIG. 15. In an example, the computer-readable storage medium comprises instructions which, when executed by the computer 1700, cause the computer 1700 to carry out the steps of a plurality of the methods 900, 1000, 1400 and 1500.

Referring back to FIG. 5, in an example, the encoder neural networks of the transmitter device 500 may be encoder neural networks of joint source channel coding variational autoencoder 1100. The transmitter device 500 comprises a first encoder neural network 212 and a second encoder neural network 222. These encoder neural networks may be examples of encoder neural network 1102 of FIG. 11 and may be part of separate joint source channel coding variational autoencoders 1100. In an example, in the transmitter device 500, each encoder neural network may be of a joint source channel coding variational autoencoder 1100 and the nodes of the channel input layer of each encoder neural network may correspond to a channel input distribution vector Z^{k}={Z₁, Z₂, . . . , Z_{K}}, the Zᵢ taking values for parameters defining a plurality of distributions, each distribution being sampleable to provide possible values for the Xᵢ of the channel input vector Xⁿ={X₁, X₂, . . . , Xₙ}. Moreover, each encoder neural network may be configured through training to map sequences of source symbols S^{m} received from the information source directly to a representation as a plurality of distributions that provide possible values for the Xᵢ of a channel input vector Xⁿ. The transmitter device 500 may also comprise a sampler (not shown), for example sampler 1606 of FIG. 16, which may be configured to produce a channel input vector Xⁿ={X₁, X₂, . . . , Xₙ} in use by sampling the respective distribution for each channel input Xᵢ defined by the channel input distribution vector Z^{k}={Z₁, Z₂, . . . , Z_{K}} output by the channel input layer of each encoder neural network. The sampler has been described above in relation to FIG. 13.

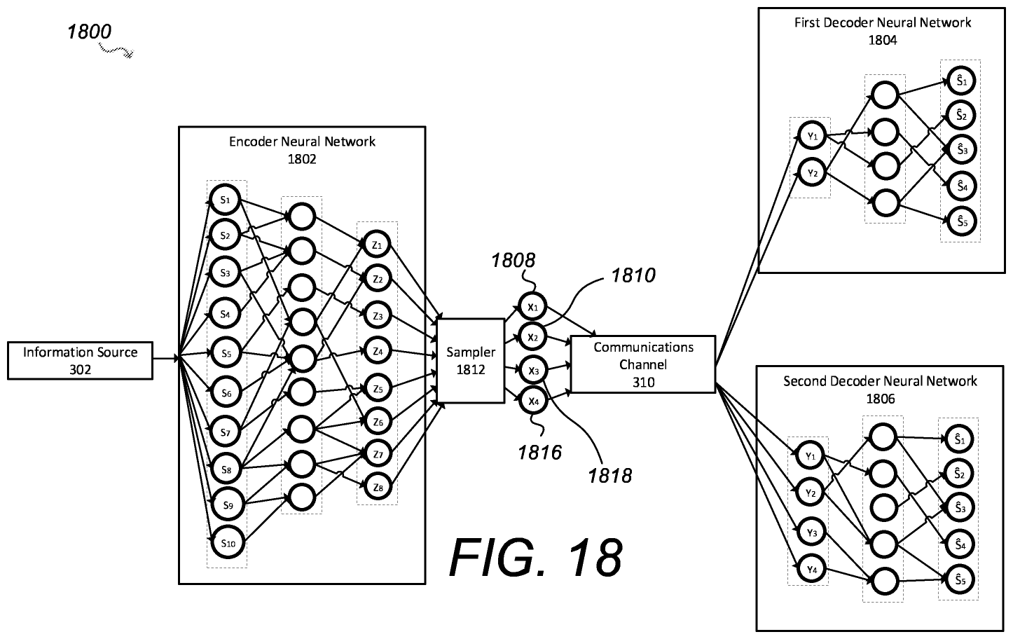

FIG. 18 provides another illustration of a communication system 1800 according to an example. The communication system 1800 of FIG. 18 is an example of the communication system 800 of FIG. 8. The communication system may comprise encoder neural network 1802, first decoder neural network 1804 and second decoder neural network 1806. Encoder neural network 1802, first decoder neural network 1804 and second decoder neural network 1806 may be of a joint source channel coding variational autoencoder, such as joint source channel coding variational encoder 1100 of FIG. 11. The nodes of the channel input layer of the encoder neural network 1802 may correspond to a channel input distribution vector Zₖ={Z₁, Z₂, . . . , Z_{K}}, the Zᵢ taking values for parameters defining a plurality of distributions, each distribution being sampleable to provide possible values for the Xᵢ of the channel input vector Xⁿ={X₁, X₂, . . . , Xₙ}. The encoder neural network 1802 may be configured through training to map sequences of source symbols S^{m} received from the information source directly to a representation as a plurality of distributions that provide possible values for the Xᵢ of a channel input vector Xⁿ.

The communication system may further comprise a sampler 1812, for example sampler 1206 of FIG. 12, configured to produce a channel input vector Xⁿ={X₁, X₂, . . . , Xₙ} in use by sampling the respective distribution for each channel input Xᵢ defined by the channel input distribution vector Z^{k}={Z₁, Z₂, . . . , Z_{K}} output by the channel input layer of the encoder neural network. For example, the sampler may receive inputs Z₁ to Z₈, sample the inputs and produce outputs X₁ 1808, X₂1810, X₃ 1818, X₄ 1816. The sampler 1812 has been described above in relation to FIG. 13.

The encoder neural network 1802 of the communication system 1800 of FIG. 18 may be included in a transmitter device such as transmitter device 1600 of FIG. 16. The transmitter device may comprise a sampler, such as sampler 1606, configured to produce a channel input vector Xⁿ={X₁, X₂, . . . , Xₙ} in use by sampling the respective distribution for each channel input Xᵢ defined by the channel input distribution vector Z^{k}={Z₁, Z₂, . . . , Z_{K}} output by the channel input layer of the encoder neural network 1802.

The method 900 of FIG. 9 and the training method 1000 of FIG. 10 may be performed for the communication system of FIG. 18. For example, for the method 900 of FIG. 9, the joint source channel coding autoencoder may be a joint source channel coding variational autoencoder, and the channel input layer may have nodes corresponding to a channel input distribution vector Z^{k}={Z₁, Z₂, . . . , Z_{K}}, the Zᵢ taking values for parameters defining a plurality of distributions, each distribution being sampleable to provide possible values for the Xᵢ of a channel input vector Xⁿ. The encoder neural network may be configured through training to map sequences of source symbols Sₘ received from the information source directly to a representation as a plurality of distributions that provide possible values for the Xᵢ of a channel input vector Xⁿ.

In another example, for the training method 1000 of FIG. 10, the joint source channel coding autoencoder may be a joint source channel coding variational autoencoder, and the sequences of source symbols S^{m} received from the information source may be mapped directly to a representation as a plurality of distributions that provide possible values for the Xᵢ of a channel input vector Xⁿ.

In summary, there is provided a communication system 800 for conveying information from an information source 302 across a communications channel 310 using a joint source channel coding autoencoder 700, comprising: an encoder neural network 702 of the joint source channel coding autoencoder 700, the encoder neural network 702 having: an input layer having input nodes corresponding to a sequence of source symbols S^{m}={S₁, S₂, . . . , Sₘ}, the Sᵢ taking values in an alphabet S, received at the input layer from the information source as samples thereof, and a channel input layer coupled to the input layer through one or more neural network layers, the channel input layer having nodes usable to provide values for the X of a channel input vector Xⁿ={X₁, X₂, . . . , Xₙ}, the Xᵢ taking values from the available input signal alphabet X of the communications channel, the channel input vector Xⁿ comprising a plurality of signal values X^{p} usable to reconstruct an information source, wherein the number p of the plurality of signal values X^{p} is smaller than the total number n of signal values of the channel input vector Xⁿ, and wherein at least one of the remaining signal values of the channel input vector Xⁿ is usable to increase the quality of the reconstructed information source, and wherein the encoder neural network is configured through training to be usable to map sequences of source symbols S^{m} received from the information source directly to a representation as a channel input vector Xⁿ, usable to drive a transmitter to transmit a corresponding signal over the communications channel; a first decoder neural network 704 and a second decoder neural network 706 of the joint source channel coding autoencoder 700, each decoder neural network having: a channel output layer having nodes corresponding to a channel output vector Y received from a receiver receiving a signal corresponding to at least the plurality of signal values X^{p} of the channel input vector Xⁿ transmitted by the transmitter and transformed by the communications channel, and an output layer coupled to the channel output layer through one or more neural network layers, having nodes matching those of the input layer of the encoder neural network, wherein the first decoder neural network is configured through training to map the representation of the source symbols as the channel output vector Y transformed by the communications channel to a reconstruction of the source symbols Ŝ^{m} output from the output layer of the joint source channel coding autoencoder, the reconstruction of the source symbols Ŝ^{m} being usable to reconstitute the information source; and wherein the number of signal values of the channel output vector Y received by the first decoder network is more than the number of signal values of the channel output vector Y received by the second decoder neural network.

Throughout the description and claims of this specification, the words “comprise” and “contain” and variations of them mean “including but not limited to”, and they are not intended to (and do not) exclude other components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed. In particular, any dependent claims may be combined with any of the independent claims and any of the other dependent claims.

1. A communication system for conveying information from an information source across a communications channel using a joint source channel coding autoencoder, comprising:
an encoder neural network of the joint source channel coding autoencoder, the encoder neural network having:
an input layer having input nodes corresponding to a sequence of source symbols S^{m}={S₁, S₂, . . . , Sₘ}, the Sᵢ taking values in an alphabet S, received at the input layer from the information source as samples thereof, and
a channel input layer coupled to the input layer through one or more neural network layers, the channel input layer having nodes usable to provide values for the Xᵢ of a channel input vector Xⁿ={X₁, X₂, . . . , Xₙ}, the Xᵢ taking values from the available input signal alphabet X of the communications channel, the channel input vector Xⁿ comprising a plurality of signal values X^{p} usable to reconstruct an information source, wherein the number p of the plurality of signal values X^{p} is smaller than the total number n of signal values of the channel input vector Xⁿ, and wherein at least one of the remaining signal values of the channel input vector Xⁿ is usable to increase the quality of the reconstructed information source, and
wherein the encoder neural network is configured through training to be usable to map sequences of source symbols S^{m} received from the information source directly to a representation as a channel input vector Xⁿ usable to drive a transmitter to transmit a corresponding signal over the communications channel;
a first decoder neural network and a second decoder neural network of the joint source channel coding autoencoder, each decoder neural network having:
a channel output layer having nodes corresponding to a channel output vector Y received from a receiver receiving a signal corresponding to at least the plurality of signal values X^{p} of the channel input vector Xⁿ transmitted by the transmitter and transformed by the communications channel, and
an output layer coupled to the channel output layer through one or more neural network layers, having nodes matching those of the input layer of the encoder neural network,
wherein the decoder neural network is configured through training to map the representation of the source symbols as the channel output vector Y transformed by the communications channel to a reconstruction of the source symbols Ŝ^{m} output from the output layer of the joint source channel coding autoencoder, the reconstruction of the source symbols Ŝ^{m} being usable to reconstitute the information source; and
wherein the number of signal values of the channel output vector Y received by the first decoder network is more than the number of signal values of the channel output vector Y received by the second decoder neural network.

2. The communication system of claim 1, wherein:
the reconstruction of the source symbols Ŝ^{m} of the first decoder neural network is of a higher quality than the reconstruction of the source symbols Ŝ^{m} of the second decoder neural network; and/or
the plurality of signal values X^{p} usable to reconstruct an information source is a plurality of consecutive symbols of the channel input vector Xⁿ.

3.-4. (canceled)

5. The communication system of claim 1, wherein:
the channel output layer of the first decoder neural network receives channel output vector Y^{p} from a receiver receiving a signal corresponding to the plurality of signal values X^{p} of the channel input vector Xⁿ; and/or
the channel output layer of the second decoder neural network receives channel output vector Yⁿ from a receiver receiving a signal corresponding to the channel input vector Xⁿ.

6. (canceled)

7. The communication system of claim 1, wherein:
each of the remaining signal values of the channel input vector Xⁿ, when received in addition to the plurality of signal values X^{p}, are usable to produce a reconstruction of the source symbols Ŝ^{m} with a higher quality than the reconstruction of the source symbols Ŝ^{m} using the plurality of signal values X^{p}; and/or
a plurality of the remaining signal values of the channel input vector Xⁿ, when received in addition to the plurality of signal values X^{p}, together are usable to produce a reconstruction of the source symbols Ŝ^{m} with a higher quality than the reconstruction of the source symbols Ŝ^{m} using the plurality of signal values X^{p}.

8.-9. (canceled)

10. The communication system of claim 1, wherein:
the first decoder neural network, the second decoder neural network and the encoder neural network are trained jointly; and/or
the number of symbols of the reconstruction of the source symbols Ŝ^{m} of the first decoder neural network is different to the number of symbols of the reconstruction of the source symbols Ŝ^{m} of the second decoder neural network.

11. (canceled)

12. The communication system of claim 1, wherein
the number of signal values p of the plurality of symbols Xₚ and/or the number of signal values n of the channel input vector Xⁿ are based on the characteristics of the communications channel and/or capabilities of the receiver comprising the second decoder neural network.

13. (canceled)

14. The communication system of claim 1, wherein:
the number of signal values p of the plurality of symbols X^{p} is such that the information source can be reconstructed at the second decoder neural network; and/or
the sequences of source symbols Ŝ^{m} received from the information source are mapped directly to a representation as a channel input vector Xⁿ.

15. (canceled)

16. The communication system of claim 1, wherein the joint source channel coding autoencoder is a joint source channel coding variational autoencoder, wherein the nodes of the channel input layer of the encoder neural network correspond to a channel input distribution vector Zₖ={Z₁, Z₂, . . . , Z_{K}}, the Zᵢ taking values for parameters defining a plurality of distributions, each distribution being sampleable to provide possible values for the Xᵢ of the channel input vector Xⁿ={X₁, X₂, . . . , Xₙ}, and wherein the encoder neural network is configured through training to map sequences of source symbols S^{m} received from the information source directly to a representation as a plurality of distributions that provide possible values for the Xᵢ of a channel input vector Xⁿ, the communication system further comprising:
a sampler, configured to produce a channel input vector Xⁿ={X₁, X₂, . . . , Xₙ} in use by sampling the respective distribution for each channel input Xᵢ defined by the channel input distribution vector Z^{k}={Z₁, Z₂, . . . , Z_{K}} output by the channel input layer of the encoder neural network.

17. (canceled)

18. The communication system of claim 1, wherein:
the size n of the channel input vector Xⁿ is smaller than the size m of the source symbols S^{m} and the information source is compressed during mapping; and/or
the size n of the channel input vector Xⁿ is based on the channel capacity.

19. (canceled)

20. The communication system of claim 1, wherein the encoder neural network and decoder neural networks are trained jointly
to minimise the difference between the input and output of the joint source channel coding variational autoencoder, and/or
based on the type of communications channel.

21. (canceled)

22. The communication system of claim 1, wherein the encoder neural network and decoder neural networks are trained jointly based on a model of the communication channel, and the decoder neural networks are trained further based on the real communication channel using one way communication of known training data samples from the transmitter to the receivers.

23. The communication system of claim 1, wherein:
the information source has not been compressed before being input into the joint source channel coding variational autoencoder; and/or
the communications channel is a noisy communications channel.

24. A transmitter device for conveying information from an information source across a communications channel using a joint source channel coding autoencoder comprising:
an encoder neural network of a joint source channel coding autoencoder, the encoder neural network comprising:
an input layer having input nodes corresponding to a sequence of source symbols S^{m}={S₁, S₂, . . . , Sₘ}, the Sᵢ taking values in a finite alphabet S, received at the input layer from an information source as samples thereof, and
a channel input layer coupled to the input layer through one or more neural network layers, the channel input layer having nodes usable to provide values for the Xᵢ of a channel input vector Xⁿ={X₁, X₂, . . . , Xₙ}, the Xᵢ taking values from the available input signal alphabet X of the communications channel, the channel input vector Xⁿ comprising a plurality of signal values X^{p} usable to reconstruct an information source, wherein the number p of the plurality of signal values X^{p} is smaller than the total number n of signal values of the channel input vector Xⁿ, and wherein at least one of the remaining signal values of the channel input vector Xⁿ is usable to increase the quality of the reconstructed information source, and
wherein the encoder neural network is configured through training to be usable to map sequences of source symbols S^{m} received from the information source directly to a representation as a channel input vector Xⁿ usable to drive a transmitter to transmit a corresponding signal over a communications channel; and
a transmitter to transmit the channel input vector Xⁿ over the communications channel.

25. The transmitter device of claim 24 in combination with:
two receiver devices, a first receiver device comprising the first decoder neural network and a second receiver device comprising the second decoder neural network; or
a receiver device comprising the first and second decoder neural networks.

26. (canceled)

27. The transmitter device of claim 24, wherein:
the sequences of source symbols S^{m} received from the information source are mapped directly to a representation as a channel input vector Xⁿ; or
the joint source channel coding autoencoder is a joint source channel coding variational autoencoder, wherein the nodes of the channel input layer of the encoder neural network correspond to a channel input distribution vector Zₖ={Z₁, Z₂, . . . , Z_{K}}, the Zᵢ taking values for parameters defining a plurality of distributions, each distribution being sampleable to provide possible values for the Xᵢ of the channel input vector Xₙ={X₁, X₂, . . . , Xₙ}, and wherein the encoder neural network is configured through training to map sequences of source symbols S^{m} received from the information source directly to a representation as a plurality of distributions that provide possible values for the Xᵢ of a channel input vector Xⁿ, the transmitter device further comprising:
a sampler, configured to produce a channel input vector Xⁿ={X₁, X₂, . . . , Xₙ} in use by sampling the respective distribution for each channel input Xᵢ defined by the channel input distribution vector Z^{k}={Z₁, Z₂, . . . , Z_{K}} output by the channel input layer of the encoder neural network.

28.-31. (canceled)

32. A training method of a communication system for conveying information from an information source across a communications channel using a joint source channel coding autoencoder comprising an encoder neural network, a first decoder neural network and a second decoder neural network, wherein the number of symbols of the channel output vector Y received by the first decoder network is more than the number of symbols of the channel output vector Y received by the second decoder neural network, the training method comprising:
mapping, by the encoder neural network of the joint source channel coding autoencoder, sequences of source symbols S^{m} received from the information source to a representation as a channel input vector Xⁿ, usable to drive a transmitter to transmit a corresponding signal over the communications channel;
for each decoder neural network:
mapping, by the decoder neural network of the joint source channel coding autoencoder, the representation of the source symbols as the channel output vector Y transformed by the communications channel to a reconstruction of the source symbols Ŝ^{m} output from the output layer of the joint source channel coding autoencoder,
comparing the sequence of source symbols S^{m} to the reconstruction of source symbols Ŝ^{m} of the decoder neural network, and
formulating a loss function for the decoder neural network based on the comparison;
amending parameters of the joint source channel coding autoencoder based on the loss functions of the decoder neural networks; and
repeating the above steps until the reconstruction of source symbols Ŝ^{m} at each decoder neural network is usable to reconstitute the information source.

33. The training method of claim 32, wherein the sequences of source symbols S^{m} received from the information source are mapped directly to a representation as a channel input vector Xⁿ; or
the joint source channel coding autoencoder is a joint source channel coding variational autoencoder, and wherein the sequences of source symbols S^{m} received from the information source are mapped directly to a representation as a plurality of distributions that provide possible values for the Xᵢ of a channel input vector Xⁿ.

34. (canceled)

35. The training method of claim 32, wherein the steps are repeated until the reconstruction of source symbols Ŝ^{m} at the second decoder neural network is usable to reconstitute the information source and the reconstruction of source symbols Ŝ^{m} at the first decoder neural network is of a higher quality than the reconstruction of source symbols Ŝ^{m} at the second decoder neural network.

36. The training method of claim 32, wherein the parameters are amended based on the weighted sum of the loss functions and/or wherein the weighting of the loss functions is amended to balance the reconstruction qualities of the first decoder neural network and the second decoder neural network.

37. The training method of claim 32, wherein the weighting of each of the loss functions is based on at least one of:
the desired reconstruction quality of the first decoder neural network and the second decoder neural network;
balancing the reconstruction qualities of the first decoder neural network and the second decoder neural network;
the requirements of the receiver of the first decoder neural network and the receiver of the second decoder neural network; and/or
the quality of the communications channel between the encoder neural network and the first decoder neural network and the quality of the communications channel between the encoder neural network and the second decoder neural network.

38.-43. (canceled)
